(19) United States
(12) Patent Application Publication
(10) Pub. No.: US 2025/0183872 A1
(43) Pub. Date: Jun. 5, 2025

(54) PIEZOELECTRIC VIBRATION ELEMENT

(71) Applicant: Murata Manufacturing Co., Ltd., Nagaokakyo-shi (JP)

(72) Inventor: Toshio NISHIMURA, Nagaokakyo-shi (JP)

(21) Appl. No.: 19/049,138

(22) Filed: Feb. 10, 2025

Related U.S. Application Data
(63) Continuation of application No. PCT/JP2024/010616, filed on Mar. 18, 2024.

(30) Foreign Application Priority Data
Jul. 31, 2023 (JP) 2023-124943

(51) Int. Cl. H03H 9/13; H03H 9/10; H03H 9/19

(52) U.S. Cl. CPC H03H 9/132; H03H 9/1035; H03H 9/19

(57) ABSTRACT

A piezoelectric vibration element according to an exemplary aspect of the present disclosure includes a piezoelectric piece having a first main surface and a second main surface. The first main surface and the second main surface face each other in a facing direction. The piezoelectric vibration element also includes a first excitation electrode on the first main surface and a second excitation electrode on the second main surface. In a plan view in the facing direction, a first area of the first excitation electrode is smaller than a second area of the second excitation electrode, and a part of the second excitation electrode overlaps an entirety of the first excitation electrode, and a first thickness of the first excitation electrode along the facing direction is smaller than a second thickness of the second excitation electrode along the facing direction.

### CROSS REFERENCE TO RELATED APPLICATIONS

The present application is a continuation of International Application No. PCT/JP2024/010616, filed Mar. 18, 2024, which claims priority to Japanese Patent Application No. 2023-124943, filed Jul. 31, 2023, the entire contents of each of which are hereby incorporated by reference in their entirety.

### TECHNICAL FIELD

The present invention relates to a piezoelectric vibration element.

### BACKGROUND

In various electronic devices such as mobile communication terminals, communication base stations, and home appliances, piezoelectric vibration elements are used for applications of timing devices, sensors, oscillators, and the like. The piezoelectric vibration element includes a piezoelectric piece having a pair of main surfaces, and a pair of excitation electrodes provided on the pair of main surfaces of the piezoelectric piece.

For example, Japanese Unexamined Patent Application Publication No. 2014-154994 (hereafter “Patent Document 1”) discloses a vibration element including a substrate that vibrates with thickness shear vibration and includes a first main surface and a second main surface that are in a relationship of front and back, a first excitation electrode that is provided on the first main surface, and a second excitation electrode that is provided on the second main surface and is larger than the first excitation electrode in plan view, in which the first excitation electrode is disposed to be accommodated within an outer edge of the second excitation electrode in plan view.

Meanwhile, with the improvement in performance of electronic devices, there is a demand for a piezoelectric vibration element having a high electromechanical coupling coefficient.

### SUMMARY OF THE INVENTION

The present disclosure has been made in view of such circumstances, and an object of the present disclosure is to provide a piezoelectric vibration element of improved electromechanical coupling coefficient.

A piezoelectric vibration element according to an exemplary aspect of the present disclosure includes a piezoelectric piece having a first main surface and a second main surface. The first main surface and the second main surface face each other in a facing direction. The piezoelectric vibration element also includes a first excitation electrode on the first main surface and a second excitation electrode on the second main surface. In a plan view in the facing direction, a first area of the first excitation electrode is smaller than a second area of the second excitation electrode, and a part of the second excitation electrode overlaps an entirety of the first excitation electrode, and a first thickness of the first excitation electrode along the facing direction is smaller than a second thickness of the second excitation electrode along the facing direction.

A piezoelectric vibration element according to an exemplary aspect of the present disclosure includes a piezoelectric piece having a first main surface and a second main surface. The first main surface and the second main surface face each other in a facing direction. The piezoelectric vibration element also includes a first excitation electrode on the first main surface, a second excitation electrode on the second main surface and an insulating film stacked on the second excitation electrode. The insulating film and the second excitation electrode are configured to form a multilayer body. In a plan view in the facing direction, a first area of the first excitation electrode is smaller than a second aera of the multilayer body, and a part of the multilayer body overlaps an entirety of the first excitation electrode, and a first thickness of the first excitation electrode along the facing direction is smaller than a sum of a second thickness of the second excitation electrode along the facing direction and a third thickness of the insulating film along the facing direction.

A piezoelectric vibration element according to an exemplary aspect of the present disclosure includes a piezoelectric piece having a first main surface and a second main surface facing the first main surface; a first excitation electrode provided on the first main surface; and a second excitation electrode provided on the second main surface, in which in plan view in a facing direction in which the first main surface and the second main surface face each other, an area of the second excitation electrode is larger than an area of the first excitation electrode, and a part of the second excitation electrode overlaps an entirety of the first excitation electrode, and a thickness of the second excitation electrode along the facing direction is larger than a thickness of the first excitation electrode along the facing direction.

A piezoelectric vibration element according to another exemplary aspect of the present disclosure includes a piezoelectric piece having a first main surface and a second main surface facing the first main surface; a first excitation electrode provided on the first main surface; a second excitation electrode provided on the second main surface; and an insulating film stacked on the second excitation electrode, in which in plan view in a facing direction in which the first main surface and the second main surface face each other, an area of a multilayer body configured of the second excitation electrode and an insulating film is larger than an area of the first excitation electrode, and a part of the multilayer body overlaps an entirety of the first excitation electrode, and a sum of a thickness of the second excitation electrode along the facing direction and a thickness of the insulating film along the facing direction is larger than a thickness of the first excitation electrode along the facing direction.

According to the present disclosure, a piezoelectric vibration element of improved electromechanical coupling coefficient is provided.

### BRIEF DESCRIPTION OF DRAWINGS

FIG. 1 is an exploded perspective view of a crystal vibrator according to a first exemplary embodiment.

FIG. 2 is a plan view of a vibration unit according to the first exemplary embodiment.

FIG. 3 is a sectional view of the vibration unit according to the first exemplary embodiment.

FIG. 4 is a graph showing a simulation result based on the first exemplary embodiment.

FIG. 5 is a sectional view of when a misalignment occurs in a first excitation electrode.

FIG. 6 is a graph showing a simulation result based on the first exemplary embodiment.

FIG. 7 is a graph showing a simulation result based on the first exemplary embodiment.

FIG. 8 is a graph showing a simulation result based on the first exemplary embodiment.

FIG. 9 is a graph showing a simulation result based on the first exemplary embodiment.

FIG. 10 is a graph showing a simulation result based on the first exemplary embodiment.

FIG. 11 is a graph showing a simulation result based on the first exemplary embodiment.

FIG. 12 is a graph showing a simulation result based on the first exemplary embodiment.

FIG. 13 is a graph showing a simulation result based on the first exemplary embodiment.

FIG. 14 is a graph showing a simulation result based on the first exemplary embodiment.

FIG. 15 is a graph showing a simulation result based on the first exemplary embodiment.

FIG. 16 is a graph showing a simulation result based on the first exemplary embodiment.

FIG. 17 is a graph showing a simulation result based on the first exemplary embodiment.

FIG. 18 is a plan view of a vibration unit according to a second exemplary embodiment.

FIG. 19 is a sectional view of the vibration unit according to the second exemplary embodiment.

FIG. 20 is a graph showing a simulation result based on the second exemplary embodiment.

FIG. 21 is a graph showing a simulation result based on the second exemplary embodiment.

FIG. 22 is a graph showing a simulation result based on the second exemplary embodiment.

FIG. 23 is a graph showing a simulation result based on the second exemplary embodiment.

FIG. 24 is a graph showing a simulation result based on the second exemplary embodiment.

FIG. 25 is a graph showing a simulation result based on the first exemplary embodiment.

FIG. 26 is a perspective view showing a configuration of a vibration unit according to a third exemplary embodiment.

FIG. 27 is a diagram showing a vibration distribution of the vibration unit according to the third exemplary embodiment.

FIG. 28 is a graph showing a simulation result based on the third exemplary embodiment.

FIG. 29 is a graph showing a simulation result based on the third exemplary embodiment.

FIG. 30 is a perspective view showing a configuration of a vibration unit according to a fourth exemplary embodiment.

FIG. 31 is a diagram showing a vibration distribution of the vibration unit according to the fourth exemplary embodiment.

FIG. 32 is a sectional view of a vibration unit according to the fifth exemplary embodiment.

FIG. 33 is a sectional view of a vibration unit according to a sixth exemplary embodiment.

FIG. 34 is a sectional view of a vibration unit according to a seventh exemplary embodiment.

FIG. 35 is a sectional view of a vibration unit according to an eighth exemplary embodiment.

### DETAILED DESCRIPTION OF EMBODIMENTS

Hereinafter, exemplary embodiments of the present disclosure will be described. In the following description of the drawings, the same or similar components are denoted by the same or similar reference numerals. The drawings are examples, and a dimension and a shape of each portion are schematic, and the technical scope of the present disclosure should not be interpreted as being limited to the embodiments.

Each drawing is attached with an orthogonal coordinate system including an X-axis, a Y′-axis, and a Z′-axis for convenience, in order to clarify a mutual relationship between the respective drawings and to help understanding of a positional relationship between respective members. The X-axis, the Y′-axis, and the Z′-axis correspond to each other in each drawing. The X-axis, the Y′-axis, and the Z′-axis respectively correspond to crystallographic axes of a crystal piece 11, which will be described later. The X-axis corresponds to an electric axis (polar axis) of the crystal, the Y-axis corresponds to a mechanical axis of the crystal, and the Z-axis corresponds to an optical axis of the crystal. The Y′-axis and the Z′-axis are axes obtained by rotating the Y-axis and the Z-axis counterclockwise around the X-axis by 0 degrees, respectively, as viewed from the positive direction of the X-axis direction.

In the following description, a direction parallel to the X-axis is referred to as an “X-axis direction”, a direction parallel to the Y′-axis is referred to as a “Y′-axis direction”, and a direction parallel to the Z′-axis is referred to as a “Z′-axis direction”. In addition, a tip direction of an arrow on the X-axis, the Y′-axis, and the Z′-axis is referred to as “positive” or “+ (plus)”, and a direction opposite to the arrow is referred to as “negative” or “−(minus)”. It is noted that, for convenience, the +Y′-axis direction is referred to as an upward direction and the −Y′-axis direction is referred to as a downward direction, but the up-down orientation of the crystal vibration element 10 and the crystal vibrator 1 is not limited. In addition, a plane specified by the X-axis and the Z′-axis is defined as a Z′X plane, and the same applies to a plane specified by other axes.

### First Exemplary Embodiment

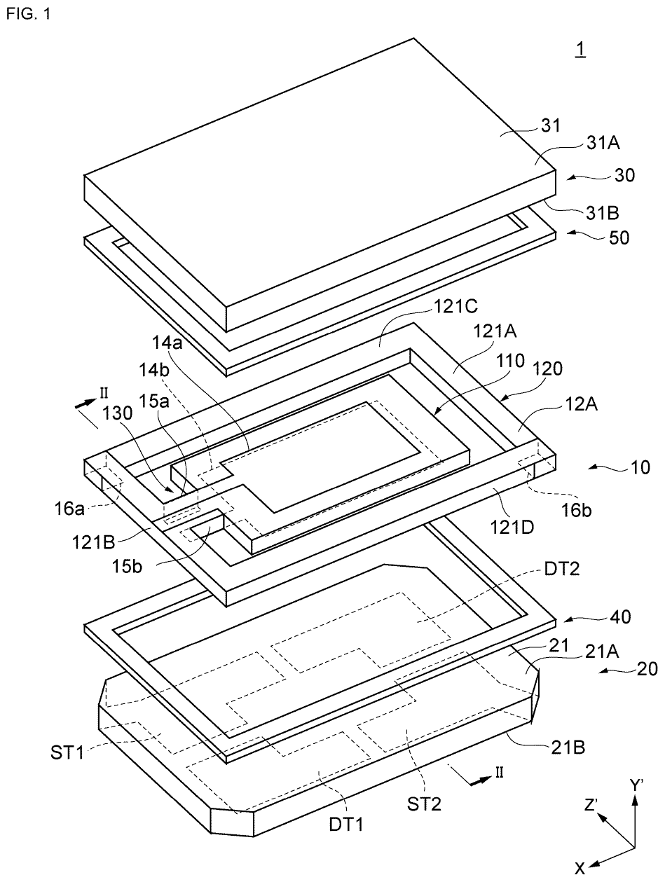

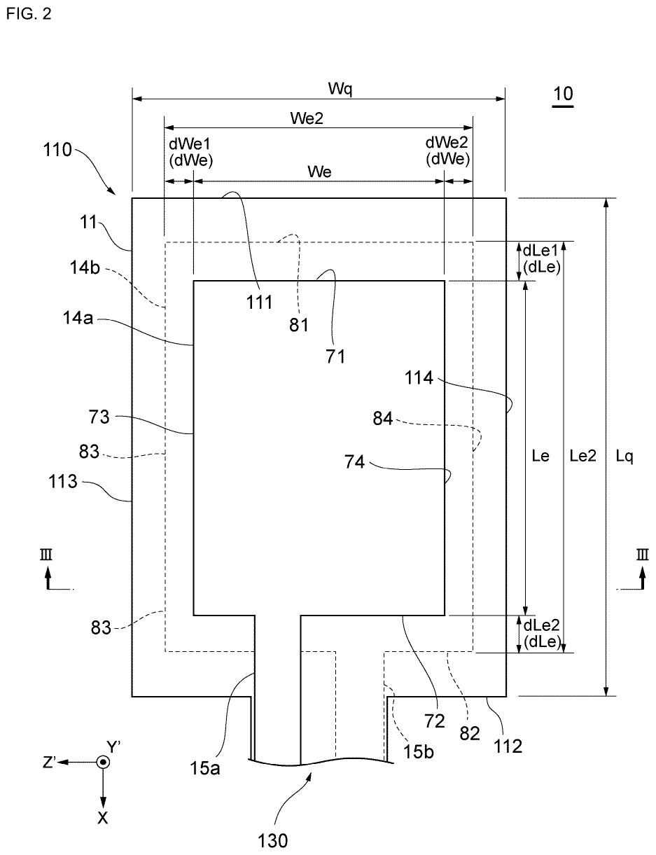

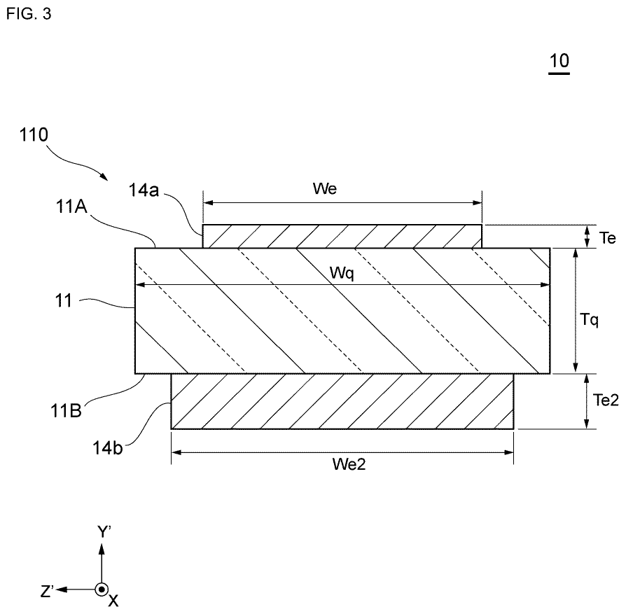

First, a configuration of a crystal vibrator according to a first exemplary embodiment will be described with reference to FIGS. 1 to 3. FIG. 1 is an exploded perspective view of the crystal vibrator according to the first exemplary embodiment. FIG. 2 is a plan view of a vibration unit according to the first exemplary embodiment. FIG. 3 is a sectional view of the vibration unit according to the first exemplary embodiment. FIG. 3 is a sectional view taken along line III-III of the vibration unit shown in FIG. 2.

The crystal vibrator 1 includes a crystal vibration element 10, a lower cover 20, an upper cover 30, a lower bonding portion 40, and an upper bonding portion 50. The lower cover 20, the crystal vibration element 10, and the upper cover 30 are arranged in this order with an interval in the Y′-axis direction. Hereinafter, a direction in which the lower cover 20, the crystal vibration element 10, and the upper cover 30 are stacked in the Y′-axis direction is referred to as a “thickness direction”. The Y′-axis direction is an example of a “facing direction”.

The crystal vibrator 1 is used as a component of, for example, a temperature compensated crystal oscillator (TCXO), a voltage controlled crystal oscillator (VCXO), or an oven controlled crystal oscillator (OCXO).

The crystal vibration element 10 is an electromechanical energy conversion element that mutually converts electric energy and mechanical energy by a piezoelectric effect. As shown in FIG. 1, the crystal vibration element 10 includes a vibration unit 110, a holding portion 120, and a support arm 130.

The vibration unit 110 is excited at a predetermined frequency based on an applied alternating voltage. The vibration unit 110 is held to be vibratable in a vibration space provided between the lower cover 20 and the upper cover 30. The main vibration of the vibration unit 110 is a thickness shear vibration mode. As shown in FIG. 2, a shape (hereinafter, referred to as a “planar shape”) of the vibration unit 110 in a plan view (hereinafter, simply referred to as “in plan view”) of the XZ′ plane is a rectangular shape having a pair of short sides 111 and 112 and a pair of long sides 113 and 114. The pair of short sides 111 and 112 extend along the Z′-axis direction and face each other in the X-axis direction. The pair of long sides 113 and 114 extend along the X-axis direction and face outward in the Z′-axis direction.

The main vibration of the vibration unit is not limited to the thickness shear vibration mode, and may be, for example, a thickness longitudinal vibration mode, a spreading vibration mode, a length vibration mode, or a bending vibration mode. In addition, the planar shape of the vibration unit is not limited to the rectangular shape, and may be, for example, a square shape, a polygonal shape, a circular shape, an elliptical shape, or a combination thereof.

The holding portion 120 (e.g., a frame) is a portion for holding the vibration unit 110. The holding portion 120 forms the vibration space of the vibration unit 110 together with the lower cover 20, the upper cover 30, the lower bonding portion 40, and the upper bonding portion 50. In plan view, the holding portion 120 is provided in a frame shape to surround the vibration unit 110 with an interval from the vibration unit 110. The holding portion 120 includes frame portions 121A, 121B, 121C, and 121D.

The frame portions 121A, 121B, 121C, and 121D are each a part of a substantially rectangular frame body that surrounds the vibration unit 110. As shown in FIGS. 1 and 2, the frame portion 121A is provided at an interval from the short side 111 of the vibration unit 110 in the X-axis direction and extends parallel to the short side 111 along the Z′-axis direction. The frame portion 121B is provided at an interval from the short side 112 of the vibration unit 110 in the X-axis direction and extends parallel to the short side 112 along the Z′-axis direction. The frame portion 121C is provided at an interval from the long side 113 of the vibration unit 110 in the Z′-axis direction and extends parallel to the long side 113 along the X-axis direction. The frame portion 121D is provided at an interval from the long side 114 of the vibration unit 110 in the Z′-axis direction and extends parallel to the long side 114 along the X-axis direction.

Both ends of the frame portion 121C are connected to one end of the frame portion 121A and one end of the frame portion 121B, respectively. Both ends of the frame portion 121D are connected to the other end of the frame portion 121A and the other end of the frame portion 121B, respectively. The frame portion 121A and the frame portion 121B face each other with the vibration unit 110 interposed therebetween in the X-axis direction. The frame portion 121C and the frame portion 121D face each other in the Z′-axis direction with the vibration unit 110 interposed therebetween.

According to exemplary aspects, the holding portion may be provided in at least a part on the periphery of the vibration unit and is not limited to a frame shape. The holding portion may be provided, for example, in a rail shape having two parallel frame portions.

The support arm 130 supports the vibration unit 110 and holds the vibration unit 110 in the holding portion 120. The support arm 130 connects the vibration unit 110 and the holding portion 120 to each other. As shown in FIGS. 1 and 2, the support arm 130 connects an end portion of the vibration unit 110 on the short side 112 side and the frame portion 121B of the holding portion 120 to each other. The support arm 130 extends along the X-axis.

The lower cover 20 faces the vibration unit 110, the holding portion 120, and the support arm 130 of the crystal vibration element 10 with an interval in the Y′-axis direction. The lower cover 20 is provided in a flat plate shape. As shown in FIG. 1, in plan view, the lower cover 20 includes a pair of long sides that extend along the X-axis direction and face each other in the Z′-axis direction, and a pair of short sides that extend along the Z′-axis direction and face each other in the Z-axis direction. In addition, the pair of long sides and the pair of short sides of the lower cover 20 are connected by sides inclined with respect to the pair of long sides and the pair of short sides. That is, notches are formed at four corners of the lower cover 20 in plan view.

The upper cover 30 faces the vibration unit 110, the holding portion 120, and the support arm 130 of the crystal vibration element 10 with an interval in the Y′-axis direction on a side opposite to the lower cover 20. The upper cover 30 is provided in a flat plate shape. As shown in FIG. 1, in plan view, the upper cover 30 has a pair of long sides that extend along the X-axis direction and face each other in the Z′-axis direction, and a pair of short sides that extend along the Z′-axis direction and face each other in the Z-axis direction. The planar shape of the upper cover 30 is a rectangular shape.

The lower bonding portion 40 and the upper bonding portion 50 are provided in a frame shape along the holding portion 120 of the crystal vibration element 10. The lower bonding portion 40 bonds the holding portion 120 of the crystal vibration element 10 and the end portion of the lower cover 20. The upper bonding portion 50 bonds the holding portion 120 of the crystal vibration element 10 and the end portion of the upper cover 30. The lower bonding portion 40 and the upper bonding portion 50 are provided by, for example, an organic-based adhesive containing an epoxy-based, vinyl-based, acrylic-based, urethane-based, or silicone-based resin.

Materials of the lower bonding portion and the upper bonding portion are not limited to the organic-based adhesive and may be provided by an inorganic-based adhesive such as a silicon-based adhesive including water glass or the like, or a calcium-based adhesive including cement or the like. The materials of the lower bonding portion and the upper bonding portion may be a low-melting-point glass (for example, a lead borate-based glass, a tin phosphate-based glass, or the like). The materials of the lower bonding portion and the upper bonding portion may be gold (Au), tin (Sn), copper (Cu), titanium (Ti), aluminum (Al), germanium (Ge), silicon (Si), or a eutectic alloy including at least one of these.

Next, a detailed configuration of the crystal vibration element 10, the lower cover 20, and the upper cover 30 will be described.

The crystal vibration element 10 includes a crystal piece 11, a first excitation electrode 14a, a second excitation electrode 14b, a first extended electrode 15a, a second extended electrode 15b, a first connection electrode 16a, and a second connection electrode 16b.

The crystal piece 11 is a type of a piezoelectric piece consisting of a piezoelectric body that vibrates according to an applied voltage. The crystal piece 11 is continuously provided over the vibration unit 110, the holding portion 120, and the support arm 130. In the XZ′ plane direction, the crystal piece 11 extends over substantially the entire region of each of the vibration unit 110, the holding portion 120, and the support arm 130. The crystal piece 11 is a crystal piece having a thin plate shape with the XZ′ plane as a main surface.

The crystal piece 11 is, for example, an AT-cut crystal piece. That is, when viewed from the X-axis positive direction side, a counterclockwise rotation angle θ of the Z′-axis and Y′-axis from the Z-axis and Y-axis is 35 degrees 15 minutes +1 minute 30 seconds. The crystal vibration element 10 using the AT cut crystal piece 11 has high frequency stability in a wide temperature range.

The cut-angles of the crystal piece are not limited to the angles described above. The rotation angles of the Y′-axis and the Z′-axis in the AT cut-type crystal piece 11 may be tilted in a range of −5 degrees or more and +15 degrees or less from 35 degrees 15 minutes. In addition, as the cut-angles of the crystal piece, a different cut other than the AT cut, for example, a BT cut, a GT cut, an SC cut, or the like may be applied.

The planar shape of the crystal piece 11 in the vibration unit 110 is a rectangular shape having a long side along the X-axis direction and a short side along the Z′-axis direction. As shown in FIG. 3, the crystal piece 11 of the vibration unit 110 has an upper surface 11A provided on the upper cover 30 side and a lower surface 11B provided on the lower cover 20 side. The upper surface 11A and the lower surface 11B correspond to an example of a pair of main surfaces facing each other in the Y′-axis direction of the crystal piece 11.

It is noted that the planar shape of the vibration unit of the crystal piece is not limited to the above. For example, the planar shape of the vibration unit of the crystal piece may be a rectangular shape having a long side extending in the Z′-axis direction and a short side extending in the X-axis direction, or may be a rectangular shape having a short side extending in the Z′-axis direction and a long side extending in the X-axis direction. The planar shape of the vibration unit of the crystal piece may be a polygonal shape, a circular shape, an elliptical shape, or a combination thereof. In addition, the vibration unit of the crystal piece is not limited to the flat plate shape. The vibration unit of the crystal piece may have a mesa-type structure or an inverse mesa-type structure having irregularities on at least one of the upper surface and the lower surface. The vibration unit of the crystal piece may have a convex structure in which an amount of a change in the thickness changes continuously or may have a bevel structure in which an amount of a change in the thickness changes discontinuously.

The first excitation electrode 14a and the second excitation electrode 14b apply an alternating voltage to the crystal piece 11 of the vibration unit 110 to excite the vibration unit 110. As shown in FIG. 3, the first excitation electrode 14a is provided on the upper surface 11A of the crystal piece 11 in the vibration unit 110, and the second excitation electrode 14b is provided on the lower surface 11b of the crystal piece 11 in the vibration unit 110. The first excitation electrode 14a and the second excitation electrode 14b face each other in the Y′-axis direction with the crystal piece 11 interposed therebetween.

As shown in FIG. 2, in plan view, an area of the second excitation electrode 14b is larger than an area of the first excitation electrode 14a, and a part of the second excitation electrode 14b overlaps the entire first excitation electrode 14a. The first excitation electrode 14a and the second excitation electrode 14b are provided at a center portion of the vibration unit 110, and a center of the first excitation electrode 14a coincides with a center of the second excitation electrode 14b.

It is noted that the positions of the first excitation electrode and the second excitation electrode are not limited to the center portion of the vibration unit. In plan view, the positions of the first excitation electrode and the second excitation electrode may be shifted toward an outer side portion from the center portion of the vibration unit. In addition, the centers of the first excitation electrode and the second excitation electrode are not limited to coinciding with each other. In plan view, the center of the first excitation electrode may be separated from the center of the second excitation electrode.

The planar shape of the first excitation electrode 14a is a rectangular shape having a long side that extends in the Z′-axis direction and a short side that extends in the X-axis direction. The planar shape of the second excitation electrode 14b is the same as the planar shape of the first excitation electrode 14a. That is, the first excitation electrode 14a and the second excitation electrode 14b have the short side parallel to the short side of the vibration unit 110 and the long side parallel to the long side of the vibration unit 110. In addition, the first excitation electrode 14a and the second excitation electrode 14b have thicknesses in the Y′-axis direction, and the thickness of the second excitation electrode 14b is larger than the thickness of the first excitation electrode 14a.

The planar shapes of the first excitation electrode and the second excitation electrode are not limited to the shape described above. The planar shapes of the first excitation electrode and the second excitation electrode may be a rectangular shape having a short side extending in the X-axis direction. In addition, the planar shapes of the first excitation electrode and the second excitation electrode may be a square shape, a polygonal shape, a circular shape, an elliptical shape, or a combination thereof. In addition, the planar shape of the first excitation electrode is not limited to the same as the planar shape of the second excitation electrode, and the planar shapes of the first excitation electrode and the second excitation electrode may be different from each other.

The first extended electrode 15a electrically connects the first excitation electrode 14a and the first connection electrode 16a. As shown in FIG. 1, the first extended electrode 15a extended from the first excitation electrode 14a extends over the vibration unit 110, the support arm 130, the upper surface of the frame portion 121B of the holding portion 120, and the side surface of the holding portion 120, and is electrically connected to the first connection electrode 16a provided on the lower surface of the holding portion 120. The second extended electrode 15b extended from the second excitation electrode 14b extends over the vibration unit 110, the lower surface, the side surface, and the upper surface of the support arm 130, the upper surfaces of the frame portions 121B and 121D of the holding portion 120, and the side surface of the holding portion 120, and is electrically connected to the second connection electrode 16b provided on the lower surface of the holding portion 120.

The first connection electrode 16a electrically connects the first excitation electrode 14a to an external terminal, and the second connection electrode 16b electrically connects the second excitation electrode 14b to the external terminal. As shown in FIG. 1, the first connection electrode 16a is provided on a lower surface (surface on the lower cover 20 side) of the crystal piece 11 at a corner portion of the holding portion 120 where the frame portion 121B and the frame portion 121C are connected to each other. The second connection electrode 16b is provided on the lower surface of the crystal piece 11 at a corner portion of the holding portion 120 where the frame portion 121A and the frame portion 121D are connected to each other.

The first excitation electrode 14a, the first extended electrode 15a, and the first connection electrode 16a are integrally provided. The same applies to the second excitation electrode 14b, the second extended electrode 15b, and the second connection electrode 16b. The electrodes of the crystal vibration element 10 have, for example, a single-layer structure made of an aluminum layer. The electrode of the crystal vibration element 10 may have a multilayer structure in which a base layer and a surface layer are stacked in this order. For example, the base layer is a chromium (Cr) layer having good adhesiveness to the crystal piece 11, and the surface layer is a gold (Au) layer having good chemical stability. The electrode of the crystal vibration element 10 may include silver (Ag), copper (Cu), titanium (Ti), molybdenum (Mo), or an aluminum copper alloy (AlCu).

The lower cover 20 includes a crystal piece 21, power terminals ST1 and ST2, and dummy terminals DT1 and DT2. The crystal piece 21 is a flat plate-shaped substrate that overlaps substantially the entire crystal vibration element 10 in plan view. The crystal piece 21 is formed of a crystal piece having the same cut-angle as the crystal piece 11 of the crystal vibration element 10. As a result, reducing thermal stress caused by a difference in thermal expansion coefficient or a difference in a direction of thermal expansion and contraction between the crystal vibration element 10 and the lower cover 20 can be achieved. As a result, suppressing the frequency variation of the crystal vibration element 10 can be achieved. The crystal piece 21 includes an upper surface 21A provided on the crystal vibration element 10 side and a lower surface 21B provided on a side opposite to the upper surface 21A. In plan view, the crystal piece 21 has a long side extending along the X-axis direction and a short side extending along the Z′-axis direction. In addition, in plan view, a side surface connecting the upper surface 21A and the lower surface 21B of the crystal piece 21 overlaps the outer side surface of the holding portion 120 in the crystal vibration element 10. Notches are formed at corner portions where the short side and the long side of the crystal piece 21 are connected to each other. An area of the crystal piece 21 in plan view is smaller than an area of a crystal piece 31, which will be described later, in plan view by an area of the notch. A shape of the side surface formed by the notch at the corner portion of the crystal piece 21 is, for example, a planar shape. However, the shape of the side surface formed by the notch at the corner portion of the crystal piece 21 is not limited to this configuration and may be a bent surface shape that is a part of a cylinder or a quadrangular prism.

The power terminals ST1 and ST2, and the dummy terminals DT1 and DT2 are provided on the lower surface 21B of the crystal piece 21. The power terminals ST1 and ST2, and the dummy terminals DT1 and DT2 correspond to an example of the external terminals of the crystal vibrator 1. The power terminals ST1 and ST2 are for applying a driving signal (driving voltage) to the crystal vibrator 1. The power terminal ST1 is electrically connected to the first connection electrode 16a via the notch of the corner portion of the crystal piece 21 and the side surface electrode provided on the outer side surface of the lower bonding portion 40. The power terminal ST2 is electrically connected to the second connection electrode 16b via the notch of the corner portion of the crystal piece 21 and the side surface electrode provided on the outer side surface of the lower bonding portion 40. The dummy terminals DT1 and DT2 are used for balancing electrical characteristics such as electrostatic capacity and mechanical strength between the power terminals ST1 and ST2. The dummy terminals DT1 and DT2 are so-called floating electrodes that are not electrically connected to the crystal vibration element 10.

At least one of the dummy terminals DT1 and DT2 may be a ground electrode that electrically grounds a part of the crystal vibrator 1.

The upper cover 30 has a crystal piece 31. The crystal piece 31 is a flat plate-shaped substrate that overlaps substantially the entire crystal vibration element 10 in plan view. The crystal piece 31 is formed of a crystal piece having the same cut-angle as the crystal piece 11 of the crystal vibration element 10. As a result, reducing thermal stress caused by a difference in thermal expansion coefficient or a difference in a direction of thermal expansion and contraction between the crystal vibration element 10 and the upper cover 30 can be achieved. As a result, suppressing the frequency variation of the crystal vibration element 10 can be achieved. The crystal piece 31 includes a lower surface 31B provided on the crystal vibration element 10 side and an upper surface 31A provided on a side opposite to the lower surface 31B. In plan view, the crystal piece 31 has a rectangular shape having a long side extending along the X-axis direction and a short side extending along the Z′-axis direction. In addition, in plan view, a side surface connecting the upper surface 31A and the lower surface 31B of the crystal piece 31 overlaps an outer side surface of the holding portion 120 in the crystal vibration element 10.

The cut-angles of the crystal pieces included in the lower cover and the upper cover are not particularly limited and may be different from the cut-angles of the crystal pieces included in the crystal vibration element. In addition, the lower cover and the upper cover may include a glass substrate, a silicon substrate, a ceramic substrate, a metal substrate, or the like instead of the crystal piece.

Next, a detailed configuration of the vibration unit 110 will be described with reference to FIGS. 2 and 3.

The first excitation electrode 14a has outer edge portions 71, 72, 73, and 74. The outer edge portion 71 is an edge portion of one side of edge portions of the four sides of the first excitation electrode 14a in plan view, extending along the Z′-axis on the X-axis negative direction side. The outer edge portion 72 is an edge portion of one side extending along the Z′-axis on the X-axis positive direction side, the outer edge portion 73 is an edge portion of one side extending along the X-axis on the Z′-axis positive direction side, and the outer edge portion 74 is an edge portion of one side extending along the X-axis on the Z′-axis negative direction side. That is, in plan view, the outer edge portion 71 is located on the frame portion 121A side, the outer edge portion 72 is located on the frame portion 121B side, the outer edge portion 73 is located on the frame portion 121C side, and the outer edge portion 74 is located on the frame portion 121D side with respect to the center portion of the first excitation electrode 14a.

The second excitation electrode 14b has outer edge portions 81, 82, 83, and 84. The outer edge portion 81 is an edge portion of one side of edge portion of the four sides of the second excitation electrode 14b in plan view, extending along the Z′-axis on the X-axis negative direction side. The outer edge portion 82 is an edge portion of one side extending along the Z′-axis on the X-axis positive direction side, the outer edge portion 83 is an edge portion of one side extending along the X-axis on the Z′-axis positive direction side, and the outer edge portion 84 is an edge portion of one side extending along the X-axis on the Z′-axis negative direction side. That is, in plan view, the outer edge portion 81 is located on the frame portion 121A side, the outer edge portion 82 is located on the frame portion 121B side, the outer edge portion 83 is located on the frame portion 121C side, and the outer edge portion 84 is located on the frame portion 121D side with respect to the center portion of the second excitation electrode 14b.

As shown in FIG. 2, in plan view, all the outer edge portions 71, 72, 73, and 74 of the first excitation electrode 14a are located further inward than the outer edge portions 81, 82, 83, and 84 of the second excitation electrode 14b. The outer edge portion 81 is adjacent to the outer edge portion 71 among the outer edge portions 71, 72, 73, and 74, the outer edge portion 82 is adjacent to the outer edge portion 72 among the outer edge portions 71, 72, 73, and 74, the outer edge portion 83 is adjacent to the outer edge portion 73 among the outer edge portions 71, 72, 73, and 74, and the outer edge portion 84 is adjacent to the outer edge portion 74 among the outer edge portions 71, 72, 73, and 74. In plan view, the outer edge portion 71 and the outer edge portion 81 are provided in parallel with each other, the outer edge portion 72 and the outer edge portion 82 are provided in parallel with each other, the outer edge portion 73 and the outer edge portion 83 are provided in parallel with each other, and the outer edge portion 74 and the outer edge portion 84 are provided in parallel with each other.

As shown in FIG. 2, in plan view, a dimension of the vibration unit 110 along the X-axis direction is defined as a length Lq, and a dimension of the vibration unit 110 along the Z′-axis direction is defined as a length Wq. A dimension of the first excitation electrode 14a along the X-axis direction is defined as a length Le, and a dimension of the first excitation electrode 14a along the Z′-axis direction is defined as a length We. A dimension of the second excitation electrode 14b along the X-axis direction is defined as a length Le2, and a dimension of the second excitation electrode 14b along the Z′-axis direction is defined as a length We2.

The length Lq is specified, for example, as a distance between the short side 111 and the short side 112 at a predetermined position along the X-axis direction. The predetermined position is, for example, on a straight line extending along the X-axis direction passing through the center of the vibration unit 110 in plan view. The length Lq may be specified as an average value or a maximum value of the distances between the short side 111 and the short side 112 along the X-axis direction. The length Wq is specified, for example, as a distance between the long side 113 and the long side 114 at a predetermined position along the Z′-axis direction. The predetermined position is, for example, on a straight line extending along the Z′-axis direction passing through the center of the vibration unit 110 in plan view. The length Wq may be specified as an average value or a maximum value of the distances between the long side 113 and the long side 114 along the Z′-axis direction.

Similarly, the length Le is specified as the distance between the outer edge portion 71 and the outer edge portion 72 along the X-axis direction at a predetermined position (for example, on a straight line passing through the center of the first excitation electrode 14a and extending along the X-axis direction), or the average value or the maximum value of the distances between the outer edge portion 71 and the outer edge portion 72 along the X-axis direction. The length We is specified as a distance between the outer edge portion 73 and the outer edge portion 74 along the Z′-axis direction at a predetermined position (for example, on a straight line passing through the center of the first excitation electrode 14a and extending along the Z′-axis direction), or an average value or a maximum value of the distances between the outer edge portion 73 and the outer edge portion 74 along the Z′-axis direction. The length Le2 is specified as the distance between the outer edge portion 81 and the outer edge portion 82 along the X-axis direction at a predetermined position (for example, on a straight line passing through the center of the second excitation electrode 14b and extending along the X-axis direction), or the average value or the maximum value of the distances between the outer edge portion 81 and the outer edge portion 82 along the X-axis direction. The length We2 is specified as the distance between the outer edge portion 83 and the outer edge portion 84 along the Z′-axis direction at a predetermined position (for example, on a straight line passing through the center of the second excitation electrode 14b and extending along the Z′-axis direction), or the average value or the maximum value of the distances between the outer edge portion 83 and the outer edge portion 84 along the Z′-axis direction.

When comparing the length Le and the length Le2, or the like, the length Le and the length Le2 are specified by the same specific method. That is, if the length Le is specified as the distance between the outer edge portion 71 and the outer edge portion 72 along the X-axis direction at the predetermined position, the length Le2 is specified as the distance between the outer edge portion 81 and the outer edge portion 82 along the X-axis direction at the predetermined position. If the length Le is specified as the average value of the distances between the outer edge portion 71 and the outer edge portion 72 along the X-axis direction, the length Le2 is specified as the average value of the distances between the outer edge portion 81 and the outer edge portion 82 along the X-axis direction. If the length Le is specified as the maximum value of the distances between the outer edge portion 71 and the outer edge portion 72 along the X-axis direction, the length Le2 is specified as the maximum value of the distances between the outer edge portion 81 and the outer edge portion 82 along the X-axis direction. When comparing other lengths, thicknesses, or the like, a specific method is also unified in the same manner.

Since the planar shape of the vibration unit 110 is a rectangular shape in which the X-axis direction is the longitudinal direction, the length Lq is larger than the length Wq (Wq<Lq). Since the planar shapes of the first excitation electrode 14a and the second excitation electrode 14b are also the same rectangular shape, the length Le is larger than the length We (We<Le), and the length Le2 is larger than the length We2 (We2<Le2). Since all the outer edge portions 81, 82, 83, and 84 of the second excitation electrode 14b are located further inward than the short sides 111 and 112 and the long sides 113 and 114 of the vibration unit 110, the length Lq is larger than the length Le2 (Le2<Lq), and the length Wq is larger than the length We2 (We2<Wq). Since all the outer edge portions 71, 72, 73, and 74 of the first excitation electrode 14a are located further inward than the outer edge portions 81, 82, 83, and 84 of the second excitation electrode 14b, the length Le2 is larger than the length Le (Le<Le2), and the length We2 is larger than the length We (We<We2). In summary, the relationship of Le<Le2<Lq and We<We2<Wq is established.

As shown in FIG. 2, in plan view, among distances between the outer edge portions of the first excitation electrode 14a and the second excitation electrode 14b, a distance between the outer edge portion 71 and the outer edge portion 81 along the X-axis direction is defined as a length dLe1, a distance between the outer edge portion 72 and the outer edge portion 82 along the X-axis direction is defined as a length dLe2, a distance between the outer edge portion 73 and the outer edge portion 83 along the Z′-axis direction is defined as a length dWe1, and a distance between the outer edge portion 74 and the outer edge portion 84 along the Z′-axis direction is defined as a length dWe2. A sum of the length dLe1 and the length dLe2 is defined as dLe (dLe=dLe1+dLe2), and a sum of the length dWe1 and the length dWe2 is defined as dWe (dWe=dWe1+dWe2).

The length dLe1 is specified, for example, as a distance between the outer edge portion 71 and the outer edge portion 81 along the X-axis direction at a predetermined position. The predetermined position is, for example, on a straight line passing through the center of the first excitation electrode 14a or the second excitation electrode 14b and extending along the X-axis direction in plan view. The length dLe1 may be specified as an average value or a maximum value of the distances between the outer edge portion 71 and the outer edge portion 81 along the X-axis direction. The length dWe1 is specified, for example, as a distance between the outer edge portion 73 and the outer edge portion 83 at a predetermined position along the Z′-axis direction. The predetermined position is, for example, on a straight line passing through the center of the first excitation electrode 14a or the second excitation electrode 14b and extending along the Z′-axis direction in plan view. The length dWe1 may be specified as an average value or a maximum value of the distances between the outer edge portion 73 and the outer edge portion 83 along the Z′-axis direction.

Similarly, the length dLe2 is specified as the distance between the outer edge portion 72 and the outer edge portion 82 along the X-axis direction at a predetermined position (for example, on a straight line passing through the center of the first excitation electrode 14a or the second excitation electrode 14b and extending along the X-axis direction), or the average value or the maximum value of the distances between the outer edge portion 72 and the outer edge portion 82 along the X-axis direction. The length dWe2 is specified as the distance between the outer edge portion 74 and the outer edge portion 84 along the Z′-axis direction at a predetermined position (for example, on a straight line passing through the center of the first excitation electrode 14a or the second excitation electrode 14b and extending along the Z′-axis direction), or the average value or the maximum value of the distances between the outer edge portion 74 and the outer edge portion 84 along the Z′-axis direction.

The length dLe is specified as a difference between the length Le and the length Le2. That is, the length dLe may be calculated based on the lengths Le2 and Le by using the expression dLe=Le2−Le, or may be calculated based on the lengths dLe1 and dLe2 by using the expression dLe=dLe1+dLe2. The length dWe is specified as a difference between the length We and the length We2. That is, the length dWe may be calculated based on the lengths We2 and We by using the expression dWe=We2−We, or may be calculated based on the lengths dWe1 and dWe2 by using the expression dWe=dWe1+dWe2.

Since the centers of the first excitation electrode 14a and the second excitation electrode 14b coincide with each other, the length dLe1 is equal to the length dLe2 and is half the size of the difference between the length Le2 and the length Le. That is, the relationship of 0<dLe1=dLe2=dLe/2=(Le2−Le)/2 is satisfied. Similarly, the length dWe1 is equal to the length dWe2 and is half the size of the difference between the length We2 and the length We. That is, the relationship of 0<dWe1=dWe2=dWe/2=(We2−We)/2 is satisfied.

It is noted that the size relationship between the length dLe1 and the length dLe2 is not limited to the above, and a relationship of 0<dLe1<dLe2 or 0<dLe2<dLe1 may be satisfied. The size relationship between the length dWe1 and the length dWe2 is not limited to the above, and a relationship of 0<dWe1<dWe2 or 0<dWe2<dWe1 may be satisfied. It is noted that as long as at least one of the lengths dLe1, dLe2, dWe1, and dWe2 is larger than 0, the other may be 0. For example, the relationship of 0=dLe1=dLe2, 0<dWe1, and 0<dWe2 may be satisfied, or the relationship of 0<dLe1, 0<dLe2, and 0=dWe1=dWe2 may be satisfied. In addition, for example, the relationship of 0=dL2, 0<dLe1, 0<dWe1, and 0<dWe2 may be satisfied. However, it is desirable that all the lengths dLe1, dLe2, dWe1, and dWe2 are larger than 0. That is, it is desirable that the relationship of 0<dLe1, 0<dLe2, 0<dWe1, and 0<dWe2 is established.

As shown in FIG. 3, a thickness of the crystal piece 11 in the vibration unit 110 is defined as Tq, a thickness of the first excitation electrode 14a is defined as Te, and a thickness of the second excitation electrode 14b is defined as Te2.

The thickness Tq is specified, for example, as a distance between the upper surface 11A and the lower surface 11B at a predetermined position along the Y′-axis direction. The predetermined position is, for example, on a straight line passing through the center of a region in which the first excitation electrode 14a and the second excitation electrode 14b face each other, and extending along the Y′-axis direction. The thickness Tq may be specified as an average value or a maximum value of distances between the upper surface 11A and the lower surface 11B along the Y′-axis direction in the region in which the first excitation electrode 14a and the second excitation electrode 14b face each other.

Similarly, the thickness Te is specified as the distance along the Y′-axis direction between the upper surface and the lower surface of the first excitation electrode 14a at a predetermined position (for example, on a straight line passing through the center of the region in which the first excitation electrode 14a and the second excitation electrode 14b face each other, and extending along the Y′-axis direction), or the average value or the maximum value of the distances along the Y′-axis direction between the upper surface and the lower surface of the first excitation electrode 14a in the region in which the first excitation electrode 14a and the second excitation electrode 14b face each other. The thickness Te2 is specified as the distance along the Y′-axis direction between the upper surface and the lower surface of the second excitation electrode 14b at a predetermined position (for example, on a straight line passing through the center of the region in which the first excitation electrode 14a and the second excitation electrode 14b face each other, and extending along the Y′-axis direction), or as an average value or a maximum value of distances between the upper surface and the lower surface of the second excitation electrode 14b along the Y′-axis direction in a region in which the first excitation electrode 14a and the second excitation electrode 14b face each other.

The thickness Tq is larger than the thickness Te2, and the thickness Te2 is larger than the thickness Te. That is, the relationship of Te<Te2<Tq is established. In addition, since the thickness of the crystal piece 11 is larger than the sum of the thicknesses of the first excitation electrode 14a and the second excitation electrode 14b, the relationship of Te+Te2<Tq is established.

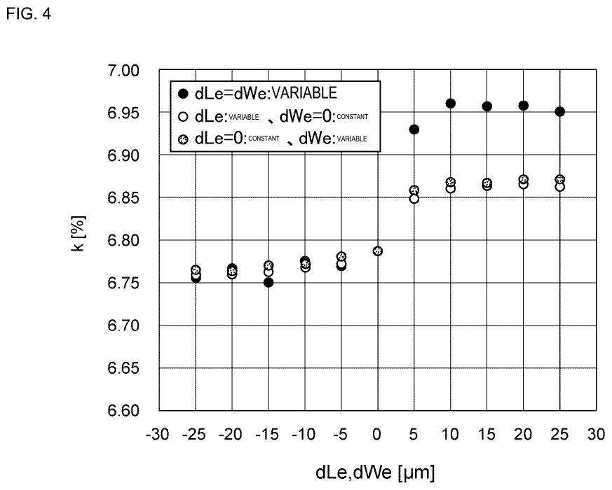

Next, a simulation result based on the first exemplary embodiment will be described with reference to FIGS. 4 to 17.

FIG. 4 is a graph showing a simulation result based on the first exemplary embodiment. In the graph of FIG. 4, the horizontal axis represents dLe or dWe (μm), and the vertical axis represents the electromechanical coupling coefficient k (%).

In FIG. 4, when the horizontal axis of the graph is larger than 0, that is, when Le2>Le or We2>We, simulation conditions are as follows:

$$Tq = 1. µm$$

$$Te = 0.05 µm$$

$$Te 2 = 0.12 µm$$

$$Lq = Wq = 120 µm$$

$$Le = 55 µm ,$$

$$We = 50 µm ,$$

$$dLe = Le 2 = 2 \times dLe 1 = 2 \times dLe 2 : variable$$

$$dWe = We 2 = 2 \times dWe 1 = 2 \times dWe 2 : variable$$

In FIG. 4, when the horizontal axis of the graph is 0 or less, that is, when Le2≤Le or We2≤We, the simulation conditions are as follows:

$$Tq = 1. µm$$

$$Te = 0.05 µm$$

$$Te 2 = 0.12 µm$$

$$Lq = Wq = 120 µm$$

$$Le 2 = 55 µm$$

$$We 2 = 50 µm$$

$$dLe = Le 2 = 2 \times dLe 1 = 2 \times dLe 2 : variable$$

$$dWe = We 2 = 2 \times dWe 1 = 2 \times dWe 2 : variable$$

The plots in the graph of FIG. 4 show the simulation results in which both dLe and dWe are used as variables with dLe=dWe, the simulation results in which dWe is used as a variable with dLe=0 (constant), and the simulation results in which dLe is used as a variable with dWe=0 (constant), respectively. The values of dLe and dWe, which are the horizontal axis in the graph of FIG. 4, indicate the values of the variables in each case. That is, the values of the horizontal axes dLe and dWe indicate both the values of dLe and dWe in which dLe=dWe is a variable, indicate the value of dWe in which dLe is a constant and dWe is a variable, and indicate the value of dLe in which dLe is a variable and dWe is a constant. Hereinafter, the value of the variable shown on the horizontal axis of the graph is expressed as “[dLe, dWe]”.

In any of a case in which dLe=dWe is a variable, a case in which dLe is a variable and dWe=0 (constant), and a case in which dLe=0 (constant) and dWe is a variable, when 0< [dLe, dWe], that is, between the first excitation electrode 14a and the second excitation electrode 14b, if the area of the second excitation electrode 14b on the thick side is larger than the area of the first excitation electrode 14a of the thin side, the electromechanical coupling coefficient k is improved From 0 μm to 10 μm, the electromechanical coupling coefficient k is improved as [dLe, dWe] is larger. In a region of 10 μm< [dLe, dWe]<25 μm, the electromechanical coupling coefficient k is substantially constant even in a case in which [dLe, dWe] is changed. In a region of −25 μm≤[dLe, dWe]≤0, the electromechanical coupling coefficient k when dLe=dWe is a variable, the electromechanical coupling coefficient k when dLe is a variable, and the electromechanical coupling coefficient k when dWe is a variable are substantially the same.

As shown in the plot in which dLe is a variable and dWe=0 (constant) and the plot in which dLe=0 (constant) and dWe is a variable, the electromechanical coupling coefficient k (%) is improved even in a case in which one of dLe and dWe is 0 and the other is larger than 0 as compared with a case in which one of dLe and dWe is 0 and the other is 0 or less. In addition, as shown in the plot in which dLe=dWe is a variable, the electromechanical coupling coefficient k (%) in which both dLe and dWe are larger than 0 is further improved as compared with the electromechanical coupling coefficient k (%) in which one of dLe and dWe is 0 and the other is larger than 0.

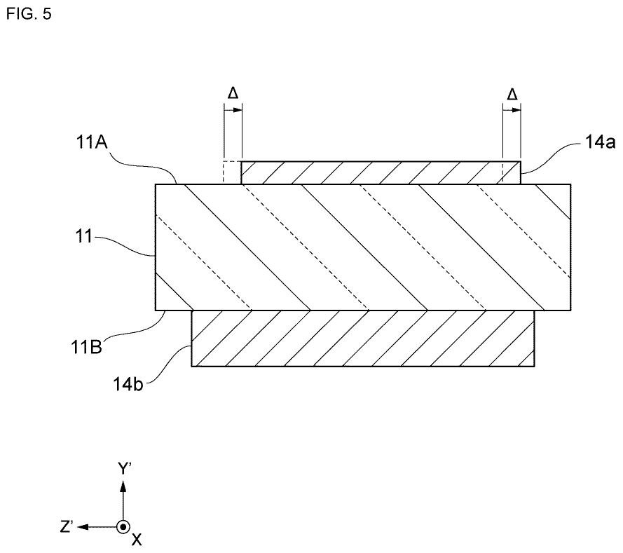

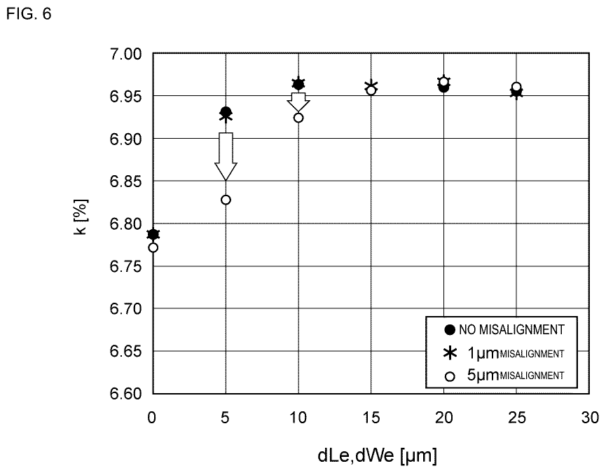

FIG. 5 is a sectional view when a misalignment occurs in the first excitation electrode. FIG. 6 is a graph showing a simulation result based on the first exemplary embodiment.

As shown in FIG. 5, FIG. 6 is a graph showing a change in the electromechanical coupling coefficient k in which the center of the first excitation electrode 14a is displaced by Δμm from the center of the second excitation electrode 14b in the X-axis direction and the Z′-axis direction in plan view. In the graph of FIG. 6, the horizontal axis represents dLe and dWe (μm), and the vertical axis represents the electromechanical coupling coefficient k (%). The size of the “misalignment” in the graph of FIG. 6 corresponds to “Δ” shown in FIG. 5. The values of the horizontal axes dLe and dWe of the graph are expressed as “[dLe, dWe]”. In FIG. 5, the simulation conditions are as follows:

$$Tq = 1. µm \\ Te = 0.05 µm \\ Te 2 = 0.12 µm \\ Lq = Wq = 120 µm \\ Le = 55 µm \\ We = 50 µm$$

$$dLe = Le 2 - Le : variable$$

$$dWe = We 2 - We : variable$$

$$dLe = dWe$$

$$dLe 1 = dLe / 2 - Δ$$

$$dLe 2 = dLe / 2 + Δ$$

$$dWe 1 = dWe / 2 - Δ$$

$$dWe 2 = dWe / 2 + Δ$$

If the relationship of dLe1=dLe/2-A<0 and dWe1=dWe/2−Δ<0, that is, dLe/2<Δ and dWe/2<Δ is established, the first excitation electrode 14a protrudes outward from the second excitation electrode 14b in plan view. If the relationship of Δ≤dLe/2 and Δ≤dWe/2 is established, even in a case of 0 μm<A, the first excitation electrode 14a does not protrude from the second excitation electrode 14b in plan view, and the entire first excitation electrode 14a overlaps a part of the second excitation electrode 14b.

The plots in the graph of FIG. 6 show the simulation results in the cases of A=0 μm, 1 μm, and 5 μm, respectively. In a case of A=0 μm, in a region in which dLe and dWe are 10 μm or more and 25 μm or less (10 μm≤[dLe, dWe]≤25 μm), the electromechanical coupling coefficient k is substantially constant regardless of dLe or dWe. In a case of Δ=0 μm, in a region in which dLe and dWe are less than 10 μm and 0 μm or more (0 μm≤[dLe, dWe]<10 μm), the electromechanical coupling coefficient k decreases as dLe and dWe decrease. In a case of Δ=1 μm, substantially the same tendency as in the case of Δ=0 μm is shown.

In a case of Δ=5 μm, in a region in which dLe and dWe are less than 10 μm and 0 or more (0 μm≤[dLe, dWe]<10 μm), the electromechanical coupling coefficient k is decreased as compared with the case of Δ=0 μm. In this case, since Δ=5 μm and 0 μm≤[dLe, dWe]<10 μm, the relationship of dLe/2<Δ and dWe/2<Δ is established, and the first excitation electrode 14a protrudes outward from the second excitation electrode 14b in plan view. That is, when the first excitation electrode 14a protrudes outward from the second excitation electrode 14b in plan view, the electromechanical coupling coefficient k is decreased as compared with the case of Δ=0 μm. On the other hand, even in a case of Δ=5 μm, in a region in which dLe and dWe are 10 μm or more and 25 μm or less (10 μm≤[dLe, dWe]≤25 μm), substantially the same tendency as in the case of Δ=0 μm is shown. In this case, since Δ=5 μm and 10 μm≤[dLe, dWe]≤25, the relationship of Δ≤dLe/2 and Δ≤dWe/2<Δ is established, and the entire first excitation electrode 14a overlaps a part of the second excitation electrode 14b.

That is, even if the center of the first excitation electrode 14a is misaligned with the center of the second excitation electrode 14b, as long as the entire first excitation electrode 14a overlaps the second excitation electrode 14b, the effect of improving the electromechanical coupling coefficient k is maintained. However, in a case in which the first excitation electrode 14a protrudes outward from the second excitation electrode 14b, the effect of improving the electromechanical coupling coefficient k is lost. Therefore, it is desirable that dLe and dWe are large in order to maintain the effect of improving the electromechanical coupling coefficient k even in a case in which the center of the first excitation electrode 14a is slightly misaligned from the center of the second excitation electrode 14b. In an exemplary aspect, the allowable range of the misalignment of the first excitation electrode 14a with respect to the second excitation electrode 14b is ½ or less of dLe and dWe. For example, in a case in which the misalignment of the first excitation electrode 14a with respect to the second excitation electrode 14b is assumed to be a maximum of 5 μm, it is desirable that dLe and dWe are 10 μm or more. In a case in which the misalignment of the first excitation electrode 14a with respect to the second excitation electrode 14b is assumed to be a maximum of 2.5 μm, it is desirable that dLe and dWe are 5 μm or more.

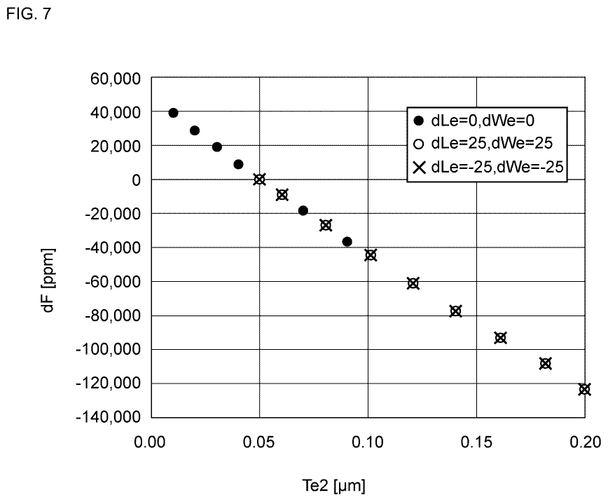

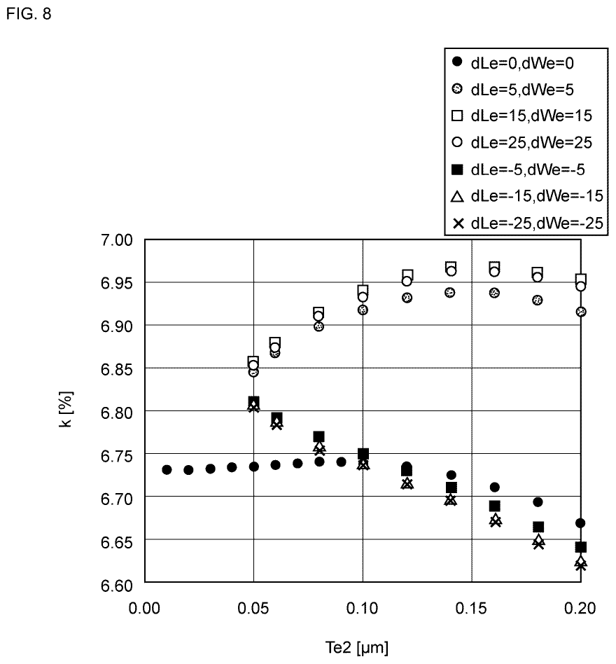

FIG. 7 is a graph showing a simulation result based on the first exemplary embodiment. FIG. 8 is a graph showing a simulation result based on the first exemplary embodiment. In the graph of FIG. 7, the horizontal axis represents Te2 (μm), and the vertical axis represents a frequency change dF (ppm) with a frequency at Te2=0.05 μm as a reference. In the graph of FIG. 8, the horizontal axis represents Te2 (μm), and the vertical axis represents the electromechanical coupling coefficient k (%).

In FIGS. 7 and 8, the simulation conditions in a case of 0 μm<dLe=dWe are as follows:

$$Tq = 1. µm \\ Te = 0.05 µm \\ Te 2 = variable \\ Lq = Wq = 120 µm \\ Le = 55 µm \\ We = 50 µm$$

$$dLe = Le 2 - Le = 2 \times dLe 1 = 2 \times dLe 2 : variable$$

$$dWe = We 2 - We = 2 \times dWe 1 = 2 \times dWe 2 : variable$$

In FIGS. 7 and 8, the simulation conditions in a case of dLe=dWe≤0 μm are as follows:

$$Tq = 1. µm \\ Te = 0.05 µm \\ Te 2 : variable \\ Lq = Wq = 120 µm \\ Le 2 = 55 µm \\ We 2 = 50 µm$$

$$dLe = Le 2 - Le = 2 \times dLe 1 = 2 \times dLe 2 : variable$$

$$dWe = We 2 - We = 2 \times dWe 1 = 2 \times dWe 2 : variable$$

As shown in FIG. 7, the dF decreases as the Te2 increases, regardless of the values of dLe and dWe. That is, the influence of the areas of the first excitation electrode 14a and the second excitation electrode 14b on the frequency is slight.

As shown in FIG. 8, in a case of dLe=dWe=0 μm, in a range of 0 μm<Te2<0.10 μm (0<Te2/Te<2), the electromechanical coupling coefficient k (%) decreases as Te2 (μm) decreases. In a range of 0.10 μm≤Te2≤0.20 μm (2≤Te2/Te≤4), the electromechanical coupling coefficient k (%) decreases as Te2 (μm) increases.

As shown in FIG. 8, in a case of dLe<0 μm and dWe<0 μm, in a range of 0.05 μm<Te2≤0.20 μm (1<Te2/Te≤4), the electromechanical coupling coefficient k (%) decreases as Te2 (μm) increases. In a range of 0.12 μm<Te2≤0.20 μm (2.4<Te2/Te≤4), the electromechanical coupling coefficient k (%) in a case of dLe<0 μm and dWe<0 μm is lower than the electromechanical coupling coefficient k (%) in a case of dLe=dWe=0 μm.

As shown in FIG. 8, in a case of 0 μm<dLe and 0 μm<dWe, in a range of 0.05 μm<Te2≤0.15 μm (1≤Te2/Te≤3), the electromechanical coupling coefficient k (%) is improved as Te2 (μm) is increased. In a range of 0.15 μm<Te2≤0.20 μm (3≤Te2/Te≤4), the electromechanical coupling coefficient k (%) decreases as Te2 (μm) increases. That is, when Te2 is about 0.15 μm (Te2/Te=3), the electromechanical coupling coefficient k (%) is maximized. In addition, in a range of 0.10 μm≤Te2≤0.20 μm (2≤Te2/Te≤4), the change in the electromechanical coupling coefficient k with respect to the change in Te2 is small, and the electromechanical coupling coefficient k is substantially constant. In a range of 0.05 μm≤Te2≤0.20 μm (1≤Te2/Te≤4), the electromechanical coupling coefficient k (%) in a case of 0 μm<dLe and 0 μm<dWe is improved with respect to the electromechanical coupling coefficient k (%) in a case of dLe=dWe=0 μm.

Therefore, between the first excitation electrode 14a and the second excitation electrode 14b, if the area of the second excitation electrode 14b on the thick side is larger than the area of the first excitation electrode 14a of the thin side, the electromechanical coupling coefficient k (%) is improved. In addition, in a range of 0.10 μm≤Te2≤0.20 μm (2≤Te2/Te≤4) in which the electromechanical coupling coefficient k (%) is stable, even if Te2 (μm) is varied to adjust the frequency, the variation in the electromechanical coupling coefficient k (%) can be suppressed.

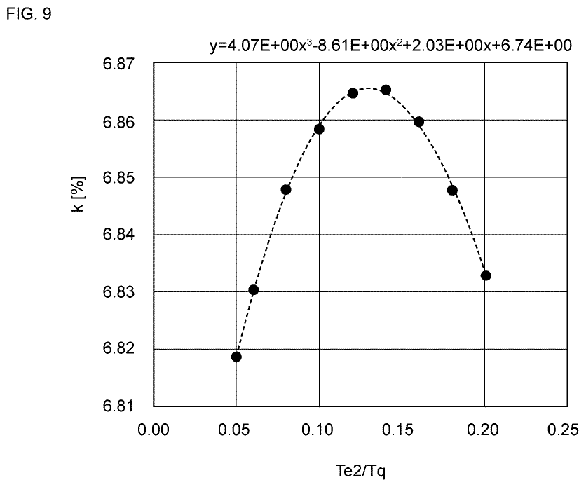

FIG. 9 is a graph showing a simulation result based on the first exemplary embodiment. In the graph of FIG. 9, the horizontal axis represents the ratio Te2/Tq of the thickness Te2 of the second excitation electrode 14b to the thickness Tq of the crystal piece 11, and the vertical axis represents the electromechanical coupling coefficient k (%).

In FIG. 9, the simulation conditions are as follows:

$$Tq = 1. µm \\ Te : 0.05$$

$$Te 2 : variable$$

$$Lq = Wq = 120 µm \\ Le = 55 µm \\ We = 50 µm \\ dLe = Le2 - Le = 2 \times dLe 1 = 2 \times dLe 2 = 25 µm \\ dWe = We 2 - We = 2 \times dWe 1 = 2 \times dWe 2 = 25 µm$$

$$ρ = 2 , 699 ( kg / {m}^{3} )$$

ρ(kg/m³) is an average density of the first excitation electrode 14a and the second excitation electrode 14b. The density of the first excitation electrode 14a is defined as p1, the density of the second excitation electrode 14b is defined as p2, the volume of the portion of the first excitation electrode 14a facing the second excitation electrode 14b is defined as V1, and the volume of the portion of the second excitation electrode 14b facing the first excitation electrode 14a is defined as V2, it is calculated by the following expression.

$$ρ = ( ρ1 \times V 1 + ρ2 \times V 2 ) / ( V 1 + V 2 )$$

If the materials of the first excitation electrode 14a and the second excitation electrode 14b are the same, a density of the material is defined as p. In the present simulation, since the materials of the first excitation electrode 14a and the second excitation electrode 14b are aluminum, p was set to 2,699 (kg/m³), which is the density of aluminum.

In a range of 0.05≤Te2/Tq≤0.20, the electromechanical coupling coefficient k (%) is maximized in the vicinity of Te2/Tq=0.13. Here, the Te2/Tq at which the electromechanical coupling coefficient k (%) is maximized is referred to as “optimum Te2/Tq”.

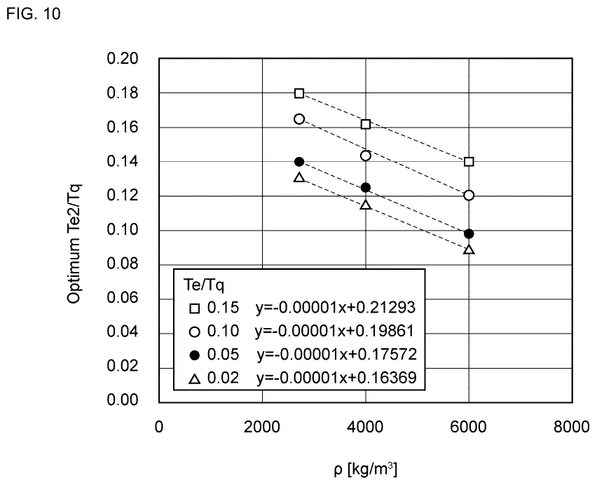

FIG. 10 is a graph showing a simulation result based on the first exemplary embodiment. In the graph of FIG. 10, the optimum Te2/Tq shown in FIG. 9 is plotted with Te and p as variables. In the graph of FIG. 10, the horizontal axis represents ρ(kg/m³), and the vertical axis represents the optimum Te2/Tq.

As the ratio Te/Tq of the thickness Te of the first excitation electrode 14a to the thickness Tq of the crystal piece 11 increases, the optimum Te2/Tq increases. In addition, in a case in which Te/Tq is set to be constant, the optimum Te2/Tq decreases as ρ(kg/m³) increases. By performing fitting of the graph shown in FIG. 10, the conditional expression in which the electromechanical coupling coefficient k (%) is maximized is obtained by the following expression:

$$Te 2 / Tq = 0.000 \; 01 \times ρ + b \pm 0.01$$

In a case of Te/Tq=0.02, b is 0.16369. In a case of Te/Tq=0.05, b=0.17572. In a case of Te/Tq=0.10, b=0.19861. In a case of Te/Tq is 0.15, b is 0.21293.

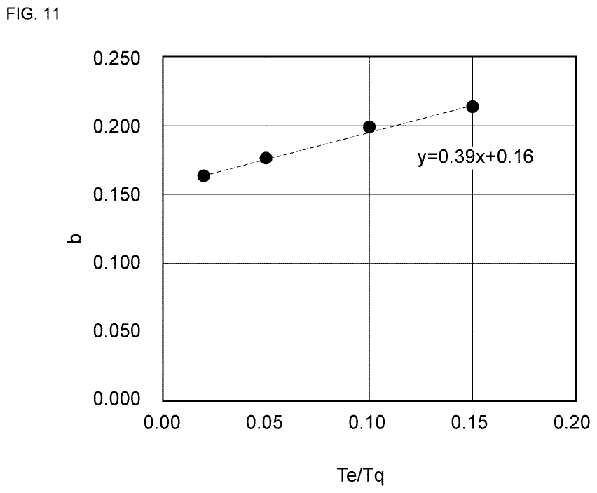

FIG. 11 is a graph showing a simulation result based on the first exemplary embodiment. In the graph of FIG. 11, b shown in FIG. 10 is plotted with Te/Tq as a variable. In the graph of FIG. 11, the horizontal axis represents Te/Tq, and the vertical axis represents b.

In a range of 0.02≤Te/Tq≤0.15, b increases as Te/Tq increases. By performing fitting of the graph shown in FIG. 11, the relationship expression between b and Te/Tq is obtained as follows:

$$b = 0.39 Te / Tq + 0.16$$

By substituting the expression obtained in FIG. 11 into the expression obtained in FIG. 10, the conditional expression in which the electromechanical coupling coefficient k (%) is maximized is obtained as follows:

$$Te 2 / Tq = 0.000 \; 01 \times ρ + 0.39 Te / Tq + 0.16 \pm 0.01$$

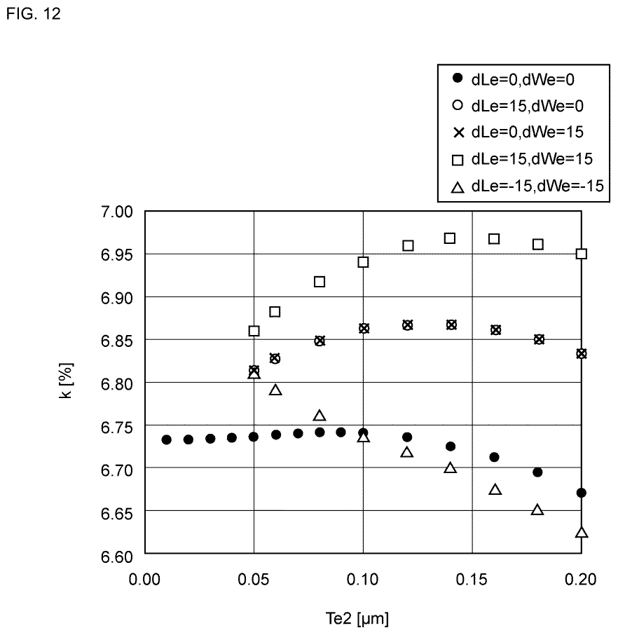

FIG. 12 is a graph showing a simulation result based on the first exemplary embodiment. In the graph of FIG. 12, the horizontal axis represents Te2 (μm), and the vertical axis represents the electromechanical coupling coefficient k (%).

In FIG. 12, the simulation conditions in a case of 0 μm<dLe=dWe are as follows:

$$T q = 1. μm \\ Te = 0.05 μm \\ Te 2 : variable \\ Lq = W q = 120 μm \\ Le = 55 μm \\ We = 50 μm \\ dLe = Le 2 - Le = 2 \times dLe 1 = 2 \times dLe 2 : variable$$

$$dWe = We 2 - We = 2 \times dWe 1 = 2 \times dWe 2 : variable$$

In FIG. 12, the simulation conditions in a case of dLe=dWe≤0 μm are as follows:

$$Tq = 1. μm \\ Te = 0.05 μm \\ Te 2 : variable$$

$$Lq = W q = 120 μm \\ Le 2 = 55 μm \\ We 2 = 50 μm \\ dLe = Le 2 - Le = 2 \times dLe 1 = 2 \times dLe 2 : variable$$

$$dWe = We 2 - We = 2 \times dWe 1 = 2 \times dWe 2 : variable$$

In a case in which one of dLe and dWe is 0 and the other is larger than 0, in a range of 0.05 μm≤Te2≤0.20 μm (1≤Te2/Te≤4), the electromechanical coupling coefficient k (%) is maximized when Te2 is 0.10 μm or more and 0.15 μm or less (2≤Te2/Te≤3). In addition, in a range of 0.10 μm≤Te2≤0.20 μm (2≤Te2/Te≤4), the change in the electromechanical coupling coefficient k with respect to the change in Te2 is small, and the electromechanical coupling coefficient k (%) is substantially constant. That is, the change in the electromechanical coupling coefficient k (%) with respect to Te2 shows the same tendency even in a case in which one of dLe and dWe is 0 and the other is larger than 0, as in a case in which both of dLe and dWe are larger than 0. However, if Te2 is the same in a range of 0.05 μm≤Te2≤0.20 μm (1≤Te2/Te≤4), the electromechanical coupling coefficient k (%) in a case in which both dLe and dWe are larger than 0 is improved with respect to the electromechanical coupling coefficient k (%) in a case in which one of dLe and dWe is 0 and the other is larger than 0.

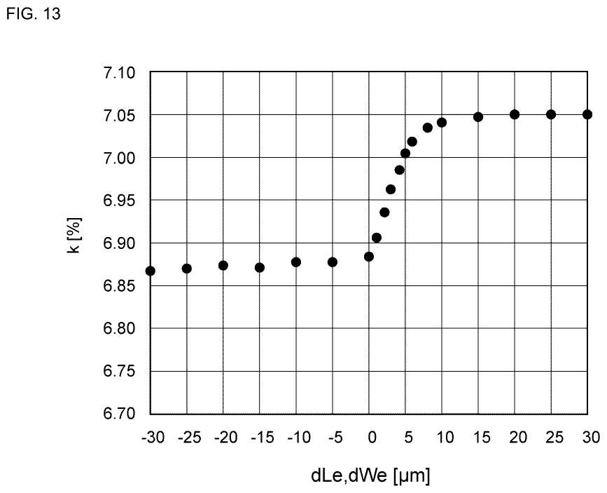

FIG. 13 is a graph showing a simulation result based on the first exemplary embodiment. In FIG. 13, the horizontal axis represents dLe and dWe (μm), and the vertical axis represents the electromechanical coupling coefficient k (%). The values of the horizontal axes dLe and dWe of the graph are expressed as “[dLe, dWe]”.

In FIG. 13, when the horizontal axis of the graph is larger than 0, that is, in a case of Le<Le2 and We<We2, the simulation conditions are as follows:

$$Tq = 1.5 μm \\ Te = 0.08 μm \\ Te 2 = 0.2 μm$$

$$Lq = W q = 120 μm \\ Le = 70 μm , \\ We = 70 μm , dLe = Le 2 - Le = 2 \times dLe 1 = 2 \times dLe 2 : variable \\ dWe = We 2 - We = 2 \times dWe 1 = 2 \times dWe 2 : variable$$

$$dLe = d We$$

In FIG. 13, when the horizontal axis of the graph is 0 or less, that is, in a case of Le2≤Le and We2≤We, the simulation conditions are as follows:

$$Tq = 1.5 μm \\ Te = 0.08 μm \\ Te 2 = 0.2 μm \\ Lq = W q = 120 μm \\ Le 2 = 70 μm \\ We 2 = 70 μm \\ dLe = Le 2 - Le = 2 \times dLe 1 = 2 \times dLe 2 : variable$$

$$dWe = We 2 - We = 2 \times dWe 1 = 2 \times dWe 2 : variable \\ dLe = d We$$

The plots in FIG. 13 show the same tendency as the plot of dLe=dWe in FIG. 4. That is, if one of the pair of excitation electrodes is thicker than the other excitation electrode and the area of the excitation electrode on the thick side is larger than the area of the excitation electrode on the thin side, even in a case in which the dimensions of the pair of excitation electrodes and the crystal piece are different from each other, the change in the electromechanical coupling coefficient k (%) with respect to the change in the dLe and dWe shows the same tendency.

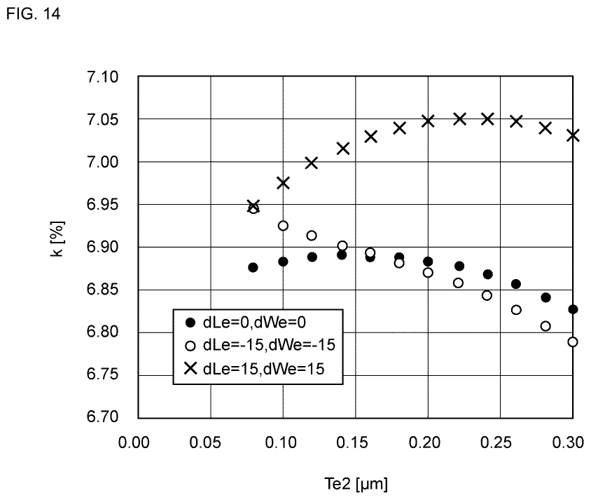

FIG. 14 is a graph showing a simulation result based on the first exemplary embodiment. In the graph of FIG. 14, the horizontal axis represents Te2 (μm), and the vertical axis represents the electromechanical coupling coefficient k (%).

In FIG. 14, the simulation conditions in a case of 0 μm<dLe=dWe are as follows:

$$Tq = 1.5 μm \\ Te = 0.08 μm \\ Te 2 : variable \\ Lq = W q = 120 μm \\ Le = 70 μm \\ We = 70 μm \\ dLe = Le 2 - Le = 2 \times dLe 1 = 2 \times dLe 2 : variable$$

$$dWe = We 2 - We = 2 \times dWe 1 = 2 \times dWe 2 : variable$$

In FIG. 14, the simulation conditions in a case of dLe=dWe≤0 μm are as follows:

$$Tq = 1.5 μm \\ Te = 0.08 μm \\ Te 2 : variable$$

$$Lq = Wq = 120 μm \\ Le = 70 μm \\ We = 70 μm \\ dLe = Le 2 - Le = 2 \times dLe 1 = 2 \times dLe 2 : variable$$

$$dWe = We 2 - We = 2 \times dWe 1 = 2 \times dWe 2 : variable$$

The plot of dLe=dWe=15 μm in FIG. 14 shows the same tendency as the plots of dLe=dWe=5 μm, 15 μm, and 25 μm in FIG. 8. That is, if one of the pair of excitation electrodes is thicker than the other excitation electrode and the area of the excitation electrode on the thick side is larger than the area of the excitation electrode on the thin side, even in a case in which the dimensions of the pair of excitation electrodes and the crystal piece are different from each other, the change in the electromechanical coupling coefficient k (%) with respect to the change in Te2 shows the same tendency.

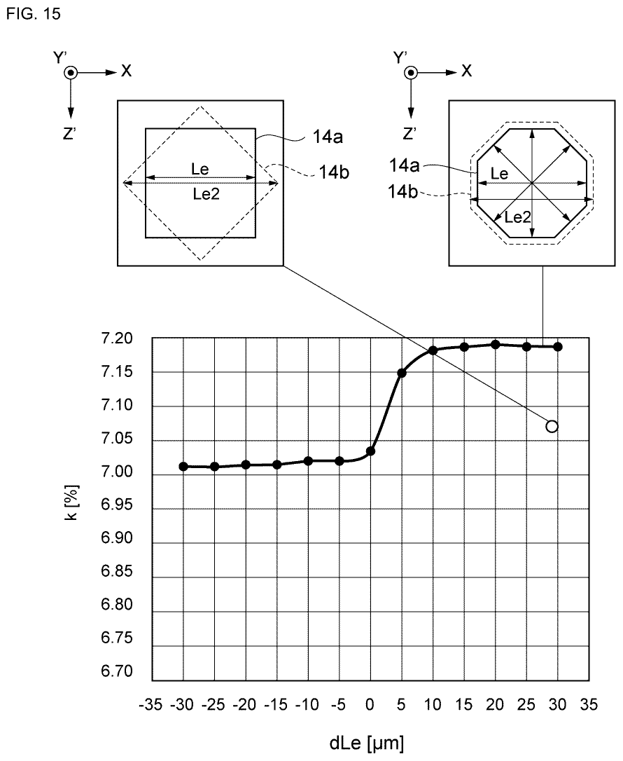

FIG. 15 is a graph showing a simulation result based on the first exemplary embodiment. In FIG. 15, the horizontal axis represents dLe (μm), and the vertical axis represents the electromechanical coupling coefficient k (%).

In FIG. 15, simulations are performed for two configuration examples in which the shapes and the areas of the overlapping portions of the first excitation electrode and the second excitation electrode are the same, and the shapes of the first excitation electrode and the second excitation electrode are different from each other.

In a first configuration example, the planar shapes of the first excitation electrode 14a and the second excitation electrode 14b are squares of equal area. Each side of the first excitation electrode 14a extends along the X-axis direction and the Z′-axis direction. The second excitation electrode 14b is disposed to be tilted by 45 degrees in a state in which the center thereof coincides with the center of the first excitation electrode 14a, and the diagonal line thereof extends along the X-axis direction and the Z′-axis direction. A shape of portions of the first excitation electrode 14a and the second excitation electrode 14b facing each other is a regular octagonal shape. A length of the first excitation electrode 14a along the X-axis direction is defined as Le, and a length of the second excitation electrode 14b along the X-axis direction is defined as Le2.

In a second configuration example, the planar shapes of the first excitation electrode 14a and the second excitation electrode 14b are regular octagons, and the centers thereof coincide with each other. A length between the sides of the first excitation electrode 14a facing each other is defined as Le, and a length between the sides of the second excitation electrode 14b facing each other is defined as Le2.

In FIG. 15, the simulation conditions are as follows:

$$T q = 1.5 μm \\ Te = 0.08 μm \\ Te 2 : 0.2 μm \\ Lq = W q = 120 μm \\ Le = 70 μm \\ dLe = Le 2 - Le : variable$$

The plot based on the second configuration example in FIG. 15 shows the same tendency as the plot of dLe=dWe in FIG. 4. That is, if the area of the excitation electrode on the thick side of the first excitation electrode 14a and the second excitation electrode 14b is larger than the area of the excitation electrode on the thin side, and a part of the excitation electrode on the thick side overlaps the entire excitation electrode on the thin side, the electromechanical coupling coefficient k (%) is improved regardless of the planar shape of the first excitation electrode 14a and the second excitation electrode 14b.

In addition, in the first configuration example, for example, dLe=Le2−Le=Le×2\hat{ }(½)−Le≈28.99>0 on the diagonal line extending in the X-axis direction of the second excitation electrode 14b. However, the electromechanical coupling coefficient k (%) in the first configuration example is approximately the same as the electromechanical coupling coefficient k (%) in the second configuration example in a range of 0 μm<dLe<5 μm, and is smaller than the electromechanical coupling coefficient k (%) in the second configuration example at the same dLe. That is, the facing area of the pair of excitation electrodes in the first configuration example is the same as the facing area of the pair of excitation electrodes in the second configuration example, and partially dLe>0, but the electromechanical coupling coefficient k (%) in the first configuration example is not improved as much as the electromechanical coupling coefficient k (%) in the second configuration example in which dLe is the same. That is, the size relationship between the areas of the first excitation electrode 14a and the second excitation electrode 14b is important in improving the electromechanical coupling coefficient k (%), rather than the size relationship between the partial lengths of the first excitation electrode 14a and the second excitation electrode 14b.

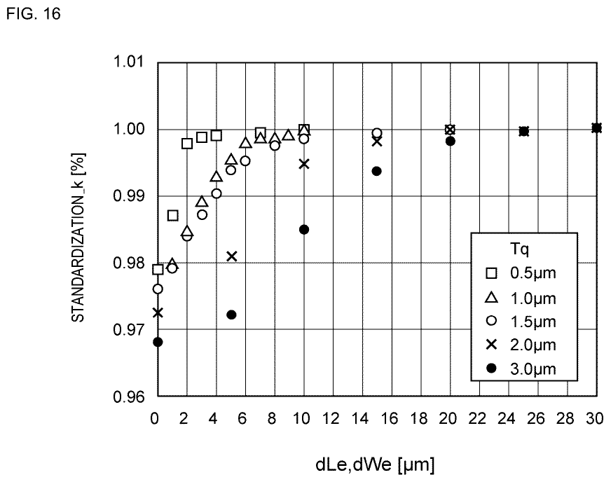

FIG. 16 is a graph showing a simulation result based on the first exemplary embodiment. In the graph of FIG. 16, the horizontal axis represents dLe and dWe (μm), and the vertical axis represents the standardized electromechanical coupling coefficient k (%). The values of the horizontal axes dLe and dWe of the graph are expressed as “[dLe, dWe]”.

In FIG. 16, the simulation conditions in a case of Tq=0.5 μm are as follows:

$$T q = 0.5 μm \\ Te = 0.05 μm \\ Te 2 = 0.12 μm \\ Lq = W q = 120 μm \\ Le = 30 μm \\ W e = 30 μm \\ dLe = Le 2 - Le = 2 \times dLe 1 = 2 \times dLe 2 : variable \\ dWe = We 2 - We = 2 \times dWe 1 = 2 \times dWe 2 : variable$$

$$dLe = d We$$

In FIG. 16, the simulation conditions in a case of the Tq=1.0 μm are as follows:

$$T q = 1. μm \\ Te = 0.05 μm \\ Te 2 = 0.12 μm \\ Lq = W q = 120 μm \\ Le = 55 μm \\ We = 50 μm \\ dLe = Le 2 - Le = 2 \times dLe 1 = 2 \times dLe 2 : variable$$

$$dWe = We 2 - We = 2 \times dWe 1 = 2 \times dWe 2 : variable \\ dLe = d We$$

In FIG. 16, the simulation conditions in a case of Tq=1.5 μm are as follows:

$$T q = 1.5 μm \\ Te = 0.05 μm \\ Te 2 = 0.12 μm \\ Lq = W q = 120 μm \\ Le = 70 μm \\ We = 70 μm \\ dLe = Le 2 - Le = 2 \times dLe 1 = 2 \times dLe 2 : variable$$

$$dWe = We 2 - We = 2 \times dWe 1 = 2 \times dWe 2 : variable \\ dLe = d We$$

In FIG. 16, the simulation conditions in a case of Tq=2.0 μm are as follows:

$$T q = 2. μm \\ Te = 0.05 μm \\ Te 2 = 0.12 μm \\ Lq = W q = 120 μm \\ Le = 55 μm \\ We = 50 μm \\ dLe = Le 2 - Le = 2 \times dLe 1 = 2 \times dLe 2 : variable$$

$$dWe = We 2 - We = 2 \times dWe 1 = 2 \times dWe 2 : variable \\ dLe = d We$$

In FIG. 16, when Tq=3.0 μm, the simulation conditions are as follows:

$$T q = 3. µm$$

$$Te = 0.05 µm$$

$$Te 2 = 0.12 µm$$

$$Lq = W q = 120 µm$$

$$Le = 55 µm$$

$$We = 50 µm$$

$$dLe = Le 2 - Le = 2 \times dLe 1 = 2 \times dLe 2 : variable$$

$$dWe = We 2 - We = 2 \times dWe 1 = 2 \times dWe 2 : variable$$

$$dLe = d W e$$

As shown in FIG. 16, dLe and dWe for improving the electromechanical coupling coefficient k (%) increase as the Tq increases. Hereinafter, the minimum dLe and dWe required to maximize the electromechanical coupling coefficient k (%) are referred to as “minimum [dLe, dWe]”.

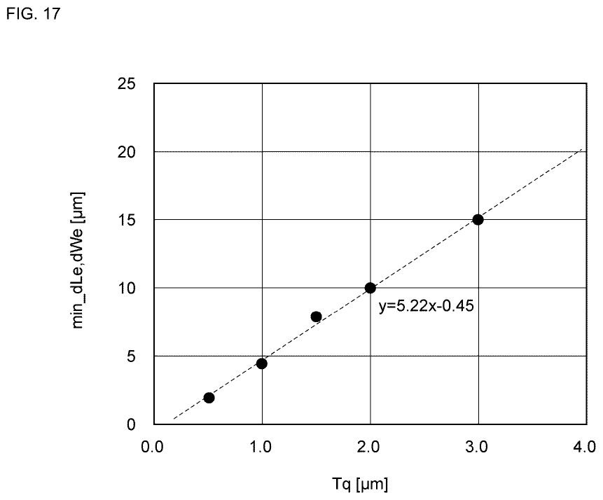

FIG. 17 is a graph showing a simulation result based on the first exemplary embodiment. In the graph of FIG. 17, the relationship between Tq and the minimum [dLe, dWe] obtained based on the graph of FIG. 16 is plotted. In the graph of FIG. 17, the horizontal axis represents Tq (μm), and the vertical axis represents the minimum [dLe, dWe] (μm).

As Tq increases, the minimum [dLe, dWe] increases. By performing fitting of the graph shown in FIG. 17, the conditional expression in which the electromechanical coupling coefficient k (%) is maximized is obtained as follows. The right side of the following expression [dLe, dWe] corresponds to an example of the distance De between the adjacent sides in a certain direction of the first excitation electrode and the second excitation electrode.

$$5.22 \times Tq - 0.45 \leq [ d Le , dWe ]$$

As described above, according to the present exemplary embodiment, the area of the second excitation electrode 14b is larger than the area of the first excitation electrode 14a, a part of the second excitation electrode 14b overlaps the entire first excitation electrode 14a, and the thickness Te2 of the second excitation electrode 14b is larger than the thickness Te of the first excitation electrode 14a.

Accordingly, the electromechanical coupling coefficient k (%) can be improved.

In addition, in the present exemplary embodiment, the first excitation electrode 14a is, for example, a side to be subjected to a trimming process in order to adjust the frequency in the manufacturing process.

Accordingly, by the trimming process, the thickness Te can be made smaller than the thickness Te2. Therefore, since Te<Te2 can be obtained without providing the first excitation electrode 14a and the second excitation electrode 14b with different thicknesses during film formation, the manufacturing process can be simplified.

In addition, in the present exemplary embodiment, the second excitation electrode 14b may be a side to be subjected to the trimming process in order to adjust the frequency.

Accordingly, since the area of the second excitation electrode 14b is larger than the area of the first excitation electrode 14a, the efficiency of adjusting the frequency by the trimming process can be increased as compared with a case of performing the trimming process on the first excitation electrode 14a. In addition, in a case in which the thickness Te2 is sufficiently larger than the thickness Te, for example, in a range of 2×Te≤Te2≤4×Te, the change in the electromechanical coupling coefficient k (%) with respect to the change in the thickness Te2 is small, so that the decrease in the electromechanical coupling coefficient k (%) can be suppressed even if the thickness Te2 is varied by the trimming process.

In addition, in the present exemplary embodiment, all the outer edge portions 71 to 74 of the first excitation electrode 14a are located further inward than the outer edge portions 81 to 84 of the second excitation electrode 14b.

Accordingly, the electromechanical coupling coefficient k (%) can be further improved than in a configuration in which a part of the outer edge portions 71 to 74 of the first excitation electrode 14a overlaps a part of the outer edge portions 81 to 84 of the second excitation electrode 14b. In addition, since the change in the electromechanical coupling coefficient k (%) with respect to the change in the thickness Te2 of the second excitation electrode 14b can be reduced, the decrease in the electromechanical coupling coefficient k (%) can be suppressed in a case in which the second excitation electrode 14b is subjected to the trimming process in order to adjust the frequency. In addition, even if the first excitation electrode 14a is misaligned with respect to the second excitation electrode 14b, the state in which the entire first excitation electrode 14a overlaps the second excitation electrode 14b is maintained, so that the decrease in the electromechanical coupling coefficient k (%) can be suppressed.

In addition, in the present exemplary embodiment, the relationship of Te2/Tq=0.00001×ρ+0.39×Te/Tq+0.16±0.01 is established.

Accordingly, when the thicknesses Tq, Te, and Te2 satisfy the conditions of the above expression, the electromechanical coupling coefficient k (%) is maximized.

In addition, in the present exemplary embodiment, at least one of the relationships of 5.22×Tq−0.45≤dLe and 5.22×Tq−0.45≤dWe is established, and it is desirable that both relationships are established.

Accordingly, suppressing the decrease in the electromechanical coupling coefficient k (%) due to the relationship of Tq, dLe, and dWe can be achieved. That is, the electromechanical coupling coefficient k (%) can be sufficiently improved.

Hereinafter, other exemplary embodiments will be described. The same or similar configurations as the configurations described in the first exemplary embodiment are denoted by the same or similar reference numerals, and descriptions thereof are appropriately omitted. In addition, the same operational effects according to the same configuration will not be sequentially described.

### Second Exemplary Embodiment

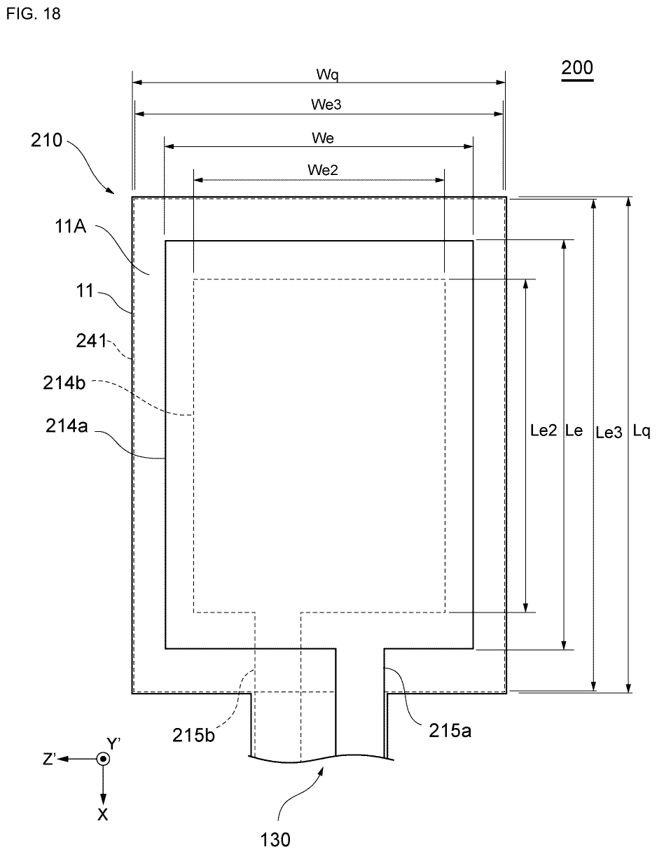

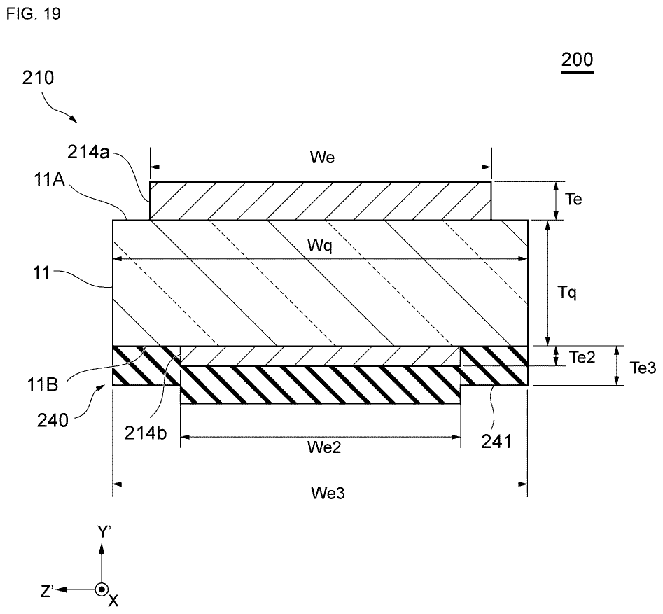

Next, the configuration of a crystal vibration element 200 according to a second exemplary embodiment will be described with reference to FIG. 18 and FIG. 19.

The area of a first excitation electrode 214a is larger than the area of a second excitation electrode 214b, the length Le of the first excitation electrode 214a is larger than the length Le2 of the second excitation electrode 214b, and the length We of the first excitation electrode 214a is larger than the length We2 of the second excitation electrode 214b. The thickness Te of the first excitation electrode 214a is larger than the thickness Te2 of the second excitation electrode 214b.

The crystal vibration element 200 further includes an insulating film 241 stacked on the second excitation electrode 214b. A material of the insulating film 241 is, for example, silicon oxide such as SiO2. However, the material of the insulating film 241 is not limited to this configuration, and may be any of an inorganic insulator such as silicon nitride, silicon oxynitride, and aluminum oxide, and an organic insulator such as polyvinylphenol, polyvinyl alcohol, ether polymer, polyimide, and acrylic resin.

As shown in FIG. 18, the insulating film 241 extends over substantially the entire region of a vibration unit 210. The area of the insulating film 241 is larger than the area of the first excitation electrode 214a and the area of the second excitation electrode 214b, and is substantially equal to the area of the vibration unit 210. Therefore, when the length of the insulating film 241 along the X-axis direction is defined as Le3 and the length of the insulating film 241 along the Z′-axis direction is defined as We3 in plan view, the relationship of Le2<Le<Le3=Lq and We2<We<We3=Wq is established. In plan view, the center of the insulating film 241 coincides with the center of the first excitation electrode 214a and the center of the second excitation electrode 214b. Therefore, an entirety of the outer edge portion of the second excitation electrode 214b is provided further inward than the outer edge portion of the first excitation electrode 214a, and an entirety of the outer edge portion of the insulating film 241 is provided further outward than the outer edge portion of the first excitation electrode 214a.

As shown in FIG. 19, the insulating film 241 is stacked on, for example, a surface of the second excitation electrode 214b on a side opposite to the crystal piece 11. When the thickness of the insulating film 241 is defined as Te3, a relationship of Te2<Te<Te3 and a relationship of Te<Te2+Te3 are established.

The thickness Te3 is specified, for example, as a distance between the upper surface and the lower surface of the insulating film 241 in a predetermined position (for example, on a straight line passing through the center of the region in which the first excitation electrode 214a, the second excitation electrode 214b, and the insulating film 241 overlap each other and extending along the Y′-axis direction) along the Y′-axis direction. The thickness Te3 may be specified as an average value, a maximum value, or a minimum value of distances between the upper surface and the lower surface of the insulating film 241 in a region in which the first excitation electrode 214a, the second excitation electrode 214b, and the insulating film 241 overlap each other along the Y′-axis direction.

The positions and the size relationship of the insulating film 241, the first excitation electrode 214a, and the second excitation electrode 214b are not limited to the above-described configurations as long as all the following conditions are satisfied. A first condition is that the insulating film 241 is stacked on an excitation electrode having a smaller area of the pair of excitation electrodes in plan view. A second condition is that a sum of a thickness of the excitation electrode having the smaller area of the pair of excitation electrodes in plan view and the thickness of the insulating film 241 is larger than a thickness of the excitation electrode having a larger area of the pair of excitation electrodes in plan view. A third condition is that an area of a multilayer body 240 configured of the excitation electrode having the smaller area of the pair of excitation electrodes in plan view and the insulating film 241 is larger than the area of the excitation electrode having the larger area of the pair of excitation electrodes in plan view. Here, the “area of the multilayer body 240” includes not only the area of the portion in which both the excitation electrode having the smaller area of the pair of excitation electrodes in plan view and the insulating film 241 overlap and extend but also the area of the portion in which only one thereof extends. A fourth condition is that a part of the multilayer body 240 in plan view overlaps the entire excitation electrode having the larger area of the pair of excitation electrodes in plan view.

For example, the configuration example shown in FIG. 18 may be modified such that the relationship of Le2<Le<Le3<Lq is established. Similarly, it may be modified such that the relationship of We2<We<We3<Wq is established.

In addition, for example, in the configuration example shown in FIG. 18, the center of the insulating film 241 in plan view may be modified to be located on the X-axis positive direction side, the X-axis negative direction side, the Z′-axis positive direction side, or the Z′-axis negative direction side with respect to the center of at least one of the first excitation electrode 214a and the second excitation electrode 214b in plan view.

In addition, for example, the configuration example shown in FIG. 19 may be modified such that Te2<Te3≤Te<Te2+Te3 is established, or may be modified such that the relationship of Te3≤Te2≤Te<Te2+Te3 is established. Similarly, it may be modified such that the relationship of Te≤Te2<Te3<Te2+Te3 is established, may be modified such that the relationship of Te≤Te3≤Te2<Te2+Te3 is established, or may be modified such that the relationship of Te<Te3≤Te2<Te2+Te3 is established.

In addition, for example, the configuration example shown in FIG. 19 may be modified such that the insulating film 241 is provided between the crystal piece 11 and the second excitation electrode 214b. The crystal vibration element 200 may further include an insulating film stacked on the first excitation electrode 214a. That is, the first insulating film may be stacked on the excitation electrode having the smaller area of the pair of excitation electrodes in plan view, and the second insulating film may be stacked on the excitation electrode having the larger area of the pair of excitation electrodes in plan view. From the viewpoint of suppressing the decrease in the electromechanical coupling coefficient k, it is desirable that the sum of the thickness of the excitation electrode having the smaller area and the thickness of the first insulating film is larger than the sum of the thickness of the excitation electrode having the larger area and the thickness of the second insulating film.

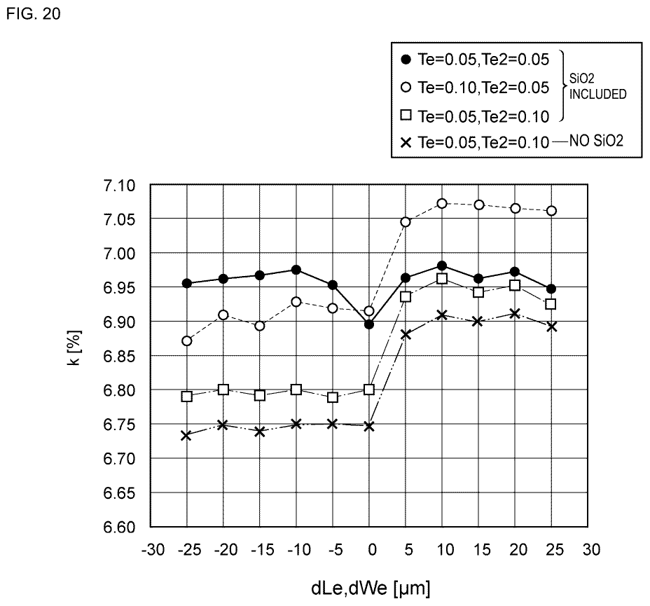

Next, a simulation result based on the second exemplary embodiment will be described with reference to FIGS. 20 to 24.

FIG. 20 is a graph showing the simulation result based on the second exemplary embodiment. In the graph of FIG. 20, the horizontal axis represents dLe and dWe (μm), and the vertical axis represents the electromechanical coupling coefficient k (%). The values of the horizontal axes dLe and dWe of the graph are expressed as “[dLe, dWe]”. “SiO2” in FIG. 20 indicates the insulating film 241. The same applies to other drawings.

In FIG. 20, in a case of Te2<Te and when [dLe, dWe] is larger than 0, that is, when Le2<Le and We<We, the simulation conditions are as follows:

$$T q = 1. µm$$

$$Te : variable$$

$$Te 2 : variable$$

$$Te 3 = 0.12 µm$$

$$Lq = W q = 120 µm$$

$$Le = 55 µm ,$$

$$We = 50 µm ,$$

$$dLe = L e - Le 2 = 2 \times dLe 1 = 2 \times dLe 2 : variable$$

$$dWe = W e - We 2 = 2 \times dWe 1 = 2 \times dWe 2 : variable$$

$$dLe = d W e$$

In FIG. 20, in a case of Te2<Te, when [dLe, dWe] is 0 or less, that is, when Le≤Le2 and We≤We2, the simulation conditions are as follows:

$$Tq = 1. µm$$

$$Te : variable$$

$$Te 2 : variable$$

$$Te 3 = 0.12 µm$$

$$Lq = Wq = 120 µm$$

$$Le 2 = 55 µm ,$$

$$We 2 = 50 µm ,$$

$$dLe = Le - Le 2 = 2 \times dLe 1 = 2 \times dLe 2 : variable$$

$$dWe = We - We 2 = 2 \times dWe 1 = 2 \times dWe 2 : variable$$

$$dLe = dW e$$

In FIG. 20, the simulation conditions in a case of Te<Te2 are the same as the simulation conditions in a case of Te2<Te, except that dLe=Le2−Le and dWe=We2−We. In FIG. 20, in a case in which “SiO2 included” is described, Le3=Lq and We3=Wq.

In any of [dLe, dWe] in a range of −25 μm≤[dLe, dWe]≤25 μm, the electromechanical coupling coefficient k (%) in a case in which Te<Te2 and the insulating film 241 is provided is improved as compared with the electromechanical coupling coefficient k (%) in a case in which the insulating film 241 is not provided. In any of [dLe, dWe] in a range of −25 μm≤[dLe, dWe]≤25 μm, the electromechanical coupling coefficient k (%) in a case in which Te2<Te and the insulating film 241 is provided is further improved than the electromechanical coupling coefficient k (%) in a case in which Te<Te2 and the insulating film 241 is provided. That is, the electromechanical coupling coefficient k (%) in a case in which the insulating film 241 is stacked on the excitation electrode on the thin side of the pair of excitation electrodes is improved as compared with the electromechanical coupling coefficient k (%) in a case in which the insulating film 241 is stacked on the excitation electrode on the thick side of the pair of excitation electrodes.

In a case of Te2<Te, the electromechanical coupling coefficient k (%) in the range of 0< [dLe, dWe] is improved as compared with the electromechanical coupling coefficient k (%) in the range of [dLe, dWe]≤0. That is, in a case of Te2<Te, the electromechanical coupling coefficient k (%) is improved when Le2<Le and We2<We. In addition, even in a case of Te<Te2, the electromechanical coupling coefficient k (%) is improved in the range of 0< [dLe, dWe] as compared with the electromechanical coupling coefficient k (%) in the range of [dLe, dWe]≤0. That is, in a case of Te<Te2, the electromechanical coupling coefficient k (%) is improved when Le<Le2 and We<We2. In summary, in a case in which the thickness of the excitation electrode of the pair of excitation electrodes on which the insulating film is stacked is smaller or larger than the thickness of the excitation electrode of the pair of excitation electrodes on which the insulating film is not stacked, the electromechanical coupling coefficient k (%) in a case in which the area of the excitation electrode on the thick side of the pair of excitation electrodes is larger than the area of the excitation electrode on the thin side is improved as compared with the electromechanical coupling coefficient k (%) in a case in which the area of the excitation electrode on the thick side of the pair of excitation electrodes is smaller than the area of the excitation electrode on the thin side.

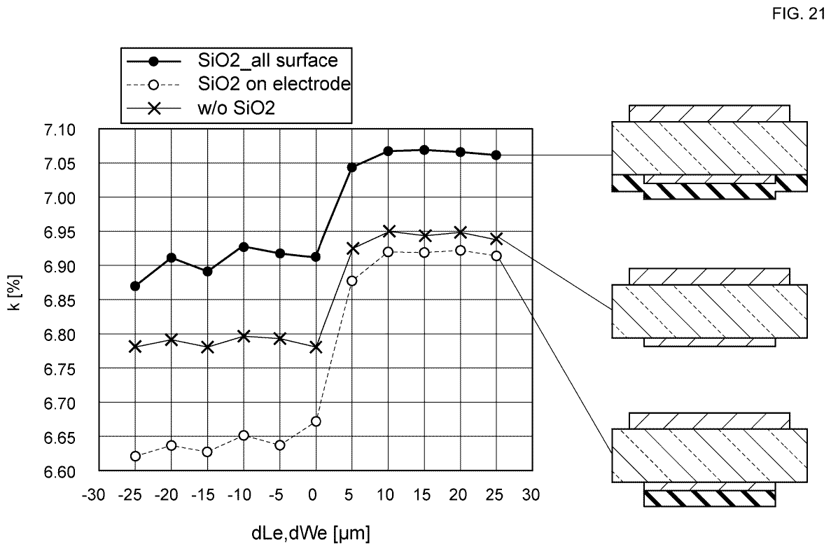

FIG. 21 is a graph showing a simulation result based on the second exemplary embodiment. In the graph of FIG. 21, the horizontal axis represents dLe and dWe (μm), and the vertical axis represents the electromechanical coupling coefficient k (%). The values of the horizontal axes dLe and dWe of the graph are expressed as “[dLe, dWe]”.

In FIG. 21, the simulation conditions are as follows when [dLe, dWe] is larger than 0, that is, when Le2<Le and We2<We.

$$T q = 1. µm$$

$$Te = 0.1 µm$$

$$Te 2 = 0.05 µm$$

$$Te 3 = 0.12 µm$$

$$Lq = W q = 120 µm$$

$$Le = 55 µm ,$$

$$We = 50 µm ,$$

$$dLe = Le - Le 2 = 2 \times dLe 1 = 2 \times dLe 2 : variable$$

$$dWe = We - We 2 = 2 \times dWe 1 = 2 \times dWe 2 : variable$$

$$dLe = dW e$$

$$Le 3 : variable$$

$$We 3 : variable$$

In FIG. 21, when [dLe, dWe] is 0 or less, that is, when Le≤Le2 and We≤We2, the simulation conditions are as follows:

$$T q = 1. µm$$

$$Te = 0.1 µm$$

$$Te 2 = 0.05 µm$$

$$Te 3 = 0.12 µm$$

$$Lq = W q = 120 µm$$

$$Le 2 = 55 µm$$

$$We 2 = 50 µm$$

$$dLe = L e - Le 2 = 2 \times dLe 1 = 2 \times dLe 2 : variable$$

$$dWe = W e - W e 2 = 2 \times dWe 1 = 2 \times dWe 2 : variable$$

$$dLe = d W e$$

$$Le 3 : variable$$

$$We 3 : variable$$

FIG. 21 plots simulation results in a case in which the insulating film 241 is provided on the entire lower surface of the vibration unit 210, in a case in which the insulating film 241 is provided only on the lower surface of the second excitation electrode 214b, and in a case in which the insulating film 241 is not provided. The case where the insulating film 241 is provided on the entire lower surface of the vibration unit 210 means that the relationship of Le3=Lq and We3=Wq is established. The case where the insulating film 241 is provided only on the lower surface of the second excitation electrode 214b means that the relationship of Le3=Le2 and We3=We2 is established. The case where the insulating film 241 is not provided means that the relationship of Le3=We3=0 is established.

In any of [dLe, dWe] in a range of −25 μm≤[dLe, dWe]≤25 μm, the electromechanical coupling coefficient k (%) in the case where the insulating film 241 is provided on the entire lower surface of the vibration unit 210 is improved as compared with the electromechanical coupling coefficient k (%) in the case where the insulating film 241 is not provided. However, in any of [dLe, dWe] in the range of −25 μm≤[dLe, dWe] ≤25 μm, the electromechanical coupling coefficient k (%) in the case where the insulating film 241 is provided only on the lower surface of the second excitation electrode 214b is lower than the electromechanical coupling coefficient k (%) in the case where the insulating film 241 is not provided.

From the above, it was shown that the effect of improving the electromechanical coupling coefficient k (%) was not obtained in a case in which the insulating film 241 is provided only in a region overlapping the excitation electrode having the smaller area of the pair of excitation electrodes in plan view. In addition, it was shown that the effect of improving the electromechanical coupling coefficient k (%) was obtained in a case in which an entirety of the outer edge portion of the second excitation electrode 214b is provided further inward than the outer edge portion of the first excitation electrode 214a and an entirety of the outer edge portion of the insulating film 241 is provided further outward than the outer edge portion of the first excitation electrode 214a in plan view.

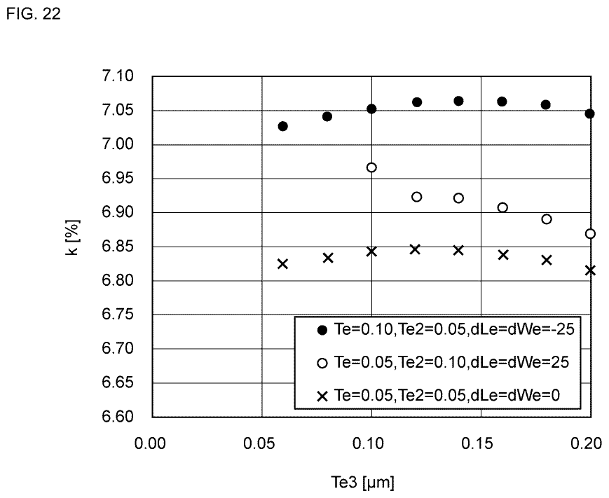

FIG. 22 is a graph showing a simulation result based on the second exemplary embodiment. In the graph of FIG. 22, the horizontal axis represents Te3 (μm), and the vertical axis represents the electromechanical coupling coefficient k (%).

In FIG. 22, the simulation conditions are as follows:

$$T q = 1. µm$$

$$Te : variable$$

$$Te 2 : variable$$

$$Te 3 : variable$$

$$Lq = W q = 120 µm$$

$$Le 2 = 55 µm$$

$$We 2 = 50 µm$$

$$Le 3 = Lq$$

$$We 3 = Wq$$

$$dLe = Le 2 - Le = 2 \times dLe 1 = 2 \times dLe 2 : variable$$

$$dWe = We 2 - We = 2 \times dWe 1 = 2 \times dWe 2 : variable$$

$$dLe = d W e$$

As shown in FIG. 22, in a range of 0.06 μm≤Te3≤0.20 μm, the electromechanical coupling coefficient k (%) in a case of Te=0.05 μm, Te2=0.10 μm, and dLe=dWe=25 μm is improved as compared with the electromechanical coupling coefficient k (%) in a case of Te=0.05 μm, Te2=0.05 μm, and dLe=dWe=0 μm. The electromechanical coupling coefficient k (%) in a case of Te=0.10 μm, Te2=0.05 μm, and dLe=dWe=−25 μm is further improved than the electromechanical coupling coefficient k (%) in a case of Te=0.05 μm, Te2=0.10 μm, and dLe=dWe=25 μm. That is, in a case in which the entire excitation electrode on the thin side overlaps a part of the excitation electrode on the thick side of the pair of excitation electrodes in plan view, the electromechanical coupling coefficient k (%) is improved regardless of which side of the excitation electrodes the insulating film is provided on. However, in a case in which the insulating film is provided in the excitation electrode on the thin side, the electromechanical coupling coefficient k (%) is improved as compared with a case where the insulating film is provided in the excitation electrode on the thick side.

In addition, in a case of Te=0.10 μm, Te2=0.05 μm, and dLe=dWe=−25 μm, the change in the electromechanical coupling coefficient k (%) with respect to the change in Te3 is small. That is, in a case in which the entire excitation electrode on the thin side overlaps a part of the excitation electrode on the thick side of the pair of excitation electrodes in plan view and the insulating film is provided in the thin excitation electrode on the thin side, the electromechanical coupling coefficient k (%) is stable with respect to the film thickness of the insulating film. That is, even if the trimming process for adjusting the frequency is performed on the insulating film in the manufacturing process, the decrease in the electromechanical coupling coefficient k (%) can be suppressed.

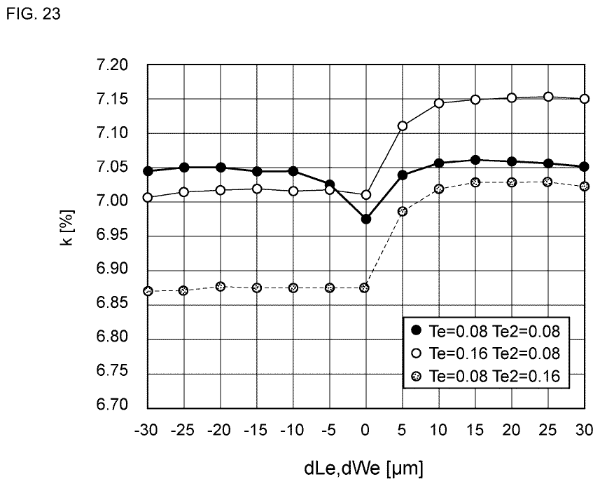

FIG. 23 is a graph showing a simulation result based on the second exemplary embodiment. In the graph of FIG. 23, the horizontal axis represents dLe and dWe (μm), and the vertical axis represents the electromechanical coupling coefficient k (%). The values of the horizontal axes dLe and dWe of the graph are expressed as “[dLe, dWe]”.

In FIG. 23, in a case of Te2<Te and [dLe, dWe] is larger than 0, that is, when Le2>Le and We2>We, the simulation conditions are as follows:

$$T q = 1.5 µm$$

$$Te : variable$$

$$Te 2 : variable$$

$$Te 3 = 0.2 µm$$

$$Lq = W q = 120 µm$$

$$Le = 70 µm ,$$

$$We = 70 µm ,$$

$$Le 3 = Lq$$

$$We 3 = Wq$$

$$dLe = L e - Le 2 = 2 \times dLe 1 = 2 \times dLe 2 : variable$$

$$dWe = W e - W e 2 = 2 \times dWe 1 = 2 \times dWe 2 : variable$$

$$dLe = d W e$$

In FIG. 23, in a case of Te2<Te and when [dLe, dWe] is 0 or less, that is, when Le2≤Le and We2≤We, the simulation conditions are as follows:

$$Tq = 1.5 µm$$

$$Te : variable$$

$$Te 2 : variable$$

$$Te 3 = 0.2 µm$$

$$Lq = Wq = 120 µm$$

$$Le 2 = 70 µm$$

$$We 2 = 70 µm$$

$$Le 3 = Lq$$

$$We 3 = Wq$$

$$dLe = Le - Le 2 = 2 \times dLe 1 = 2 \times dLe 2 : variable$$

$$dWe = We - W e 2 = 2 \times dWe 1 = 2 \times dWe 2 : variable$$

$$dLe = dW e$$

In FIG. 23, the simulation conditions in a case of Te<Te2 are the same as the simulation conditions in a case of Te2<Te, except dLe=Le2−Le and dWe=We2−We.

The plot in FIG. 23 shows the same tendency as the plot of “SiO2 included” in FIG. 20. That is, if the size relationship between the respective dimensions of the pair of excitation electrodes and the insulating film is the same, even in a case in which the respective dimensions of the pair of excitation electrodes and the insulating film are different from each other, the change in the electromechanical coupling coefficient k (%) with respect to the change in [dLe, dWe] shows the same tendency.

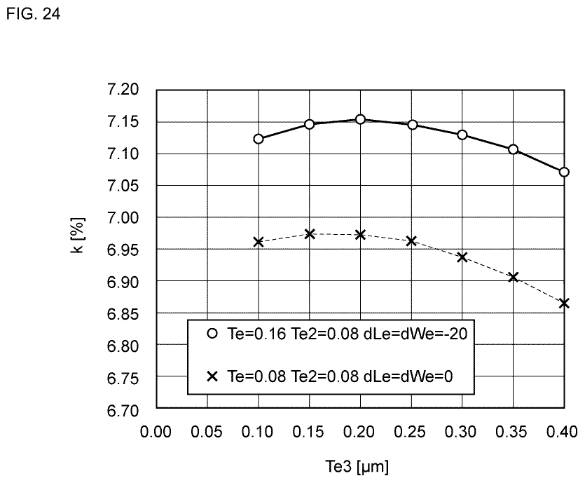

FIG. 24 is a graph showing a simulation result based on the second exemplary embodiment. In the graph of FIG. 24, the horizontal axis represents Te3 (μm), and the vertical axis represents the electromechanical coupling coefficient k (%).

In FIG. 24, the simulation conditions are as follows:

$$Tq = 1.5 µm$$

$$Te : variable$$

$$Te 2 = 0.08 µm$$

$$Te 3 : variable$$

$$Lq = Wq = 120 µm$$

$$Le 2 = 70 µm$$

$$We 2 = 70 µm$$

$$Le 3 = Lq$$

$$We 3 = Wq$$

$$dLe = Le 2 - Le = 2 \times dLe 1 = 2 \times dLe 2 : variable$$

$$dWe = We 2 - We = 2 \times dWe 1 = 2 \times dWe 2 : variable$$

$$dLe = dWe$$

The plot of Te=0.16 μm, Te2=0.08 μm, and dLe=dWe=−20 μm in FIG. 24 shows the same tendency as the plot of Te=0.10 μm, Te2=0.05 μm, and dLe=dWe=−25 μm in FIG. 22. That is, if the size relationship between the respective dimensions of the pair of excitation electrodes and the insulating film is the same, even in a case in which the respective dimensions of the pair of excitation electrodes and the insulating film are different from each other, the change in the electromechanical coupling coefficient k (%) with respect to the change in Te3 is the same tendency.

As described above, according to the present exemplary embodiment, in plan view, the area of the multilayer body 240 configured of the second excitation electrode 214b and the insulating film 241 is larger than the area of the first excitation electrode 214a, and a part of the multilayer body 240 overlaps the entire first excitation electrode 214a. A sum of the thickness Te2 of the second excitation electrode 214b and the thickness Te3 of the insulating film 241 is larger than the thickness Te of the first excitation electrode 214a.

Accordingly, the electromechanical coupling coefficient k (%) can be improved.

In addition, in the present exemplary embodiment, the insulating film 241 is stacked on a surface of the second excitation electrode 214b on a side opposite to the crystal piece 11.

Accordingly, the distance between the first excitation electrode 214a and the second excitation electrode 214b can be made smaller than that in a configuration in which the insulating film 241 is present between the first excitation electrode 214a and the second excitation electrode 214b. As a result, since the portion that vibrates due to the piezoelectric effect can be made thin, the crystal vibration element 200 can be made high frequency.

In addition, in the present exemplary embodiment, an entirety of the outer edge portion of the second excitation electrode 214b is provided further inward than the outer edge portion of the first excitation electrode 214a, and an entirety of the outer edge portion of the insulating film 241 is provided further outward than the outer edge portion of the first excitation electrode 214a.

As a result, since the change in the electromechanical coupling coefficient k (%) with respect to the change in the thickness Te3 of the insulating film 241 can be reduced, suppressing the decrease in the electromechanical coupling coefficient k (%) can be achieved when the insulating film 241 is subjected to the trimming process in order to adjust the frequency.

In addition, in the present exemplary embodiment, the thickness Te2 of the second excitation electrode 214b is smaller than the thickness Te of the first excitation electrode 214a.

Accordingly, the electromechanical coupling coefficient k (%) can be further improved.

In addition, in the present exemplary embodiment, the relationship of (Te2+Te3)/Tq=0.00001×p′+0.39×Te/Tq+0.16+0.01 is established. p′ is an average density of the first excitation electrode 214a, the second excitation electrode 214b, and the insulating film 241. When the density of the first excitation electrode 214a is defined as ρ1, the density of the second excitation electrode 214b is defined as ρ2, the density of the insulating film 241 is defined as ρ3, the volume of the portion of the first excitation electrode 214a facing the second excitation electrode 214b and the insulating film 241 is defined as V1, the volume of the portion of the second excitation electrode 214b facing the first excitation electrode 214a and the insulating film 241 is defined as V2, and the volume of the portion of the insulating film 241 facing the first excitation electrode 214a and the second excitation electrode 214b is defined as V3, the calculation is performed by the following expression.

$${ρ}^{′} = ( ρ1 \times V 1 + ρ2 \times V 2 + ρ3 \times V 3 ) / ( V 1 + V 2 + V 3 )$$

Accordingly, when the thicknesses Tq, Te, Te2, and Te3 satisfy the conditions of the above-described expression, the electromechanical coupling coefficient k (%) is maximized, as in the first exemplary embodiment.

In addition, in the present exemplary embodiment, the materials of the first excitation electrode 214a and the second excitation electrode 214b are aluminum, and the material of the insulating film 241 is silicon oxide.

Accordingly, since the density of aluminum and the density of silicon oxide are close to each other, the calculation of the average density p′ can be simplified. In addition, the adhesiveness between the crystal piece 11 and the insulating film 241 is good, and the adhesiveness between the crystal piece 11 and the second excitation electrode 214b can be substantially the same as the adhesiveness between the second excitation electrode 214b and the insulating film 241. Therefore, suppressing peeling of the insulating film 241 from the crystal piece 11 or the second excitation electrode 214b, or the peeling of the second excitation electrode 214b from the crystal piece 11 can be achieved.

### Third Exemplary Embodiment

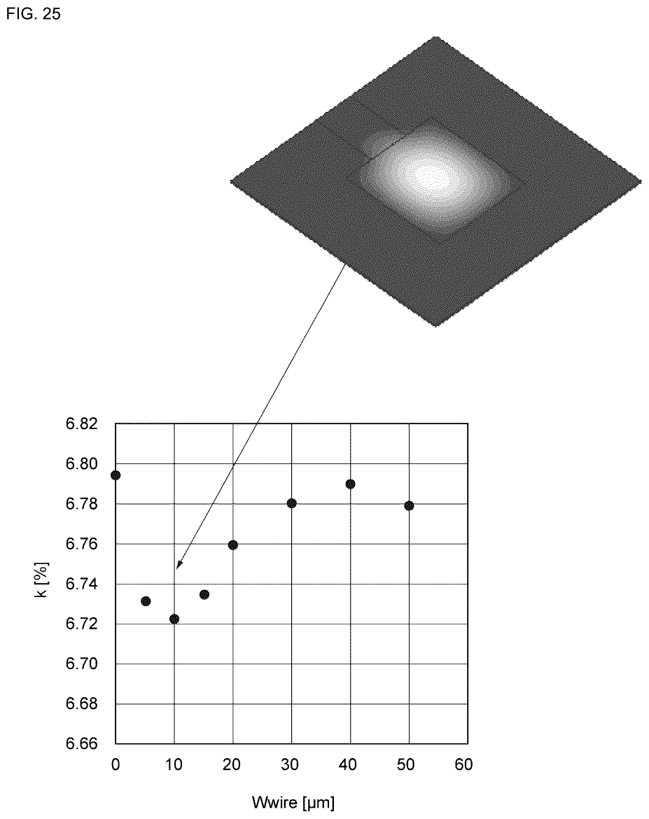

Next, a configuration of a crystal vibration element 300 according to a third exemplary embodiment will be described with reference to FIGS. 25 to 29.

FIG. 25 is a graph showing a simulation result based on the first exemplary embodiment. In an exemplary aspect, the simulation result of the electromechanical coupling coefficient k (%) calculated in consideration of the influence of the second extended electrode 15b is shown. In the graph of FIG. 25, the horizontal axis represents a wiring width Wwire (μm) of the extended electrode, and the vertical axis represents the electromechanical coupling coefficient k (%). The wiring width of the extended electrode is a dimension of the first extended electrode 15a extending in the X-axis direction along the Z′-axis direction.

In FIG. 25, the simulation conditions are as follows. It is noted that the first extended electrode 15a is extended from the center portion of the outer edge portion of the first excitation electrode 14a on the X-axis positive direction side in the Z′-axis direction.

$$T q = 1. µm$$

$$Te = 0.05 µm$$

$$Te 2 = 0.05 µm$$

$$Lq = W q = 120 µm$$

$$Le = 55 µm$$

$$We = 50 µm$$

$$Le 2 = 70 µm$$

$$We 2 = 60 µm$$

$$dLe = Le 2 - Le = 2 \times dLe 1 = 2 \times dLe 2 = 15 µm$$

$$dWe = We 2 - We = 2 \times dWe 1 = 2 \times dWe 2 = 10 µm$$

$$Wwire : variable$$

In a case of Wwire=0 μm, that is, in a case in which the simulation of the excitation is performed only with the first excitation electrode 14a and the second excitation electrode 14b without providing the first extended electrode 15a, a region in which the first excitation electrode 14a and the second excitation electrode 14b overlap with each other is excited. However, in a case in which 0 μm<Wwire is set, a region in which the second excitation electrode 14b and the first extended electrode 15a overlap with each other is also excited. Therefore, as shown in FIG. 25, the electromechanical coupling coefficient k (%) when 0 μm<Wwire is lower than the electromechanical coupling coefficient k (%) when Wwire=0 μm. In a case of 0 μm<Wwire, the Q value is also decreased.

As shown in FIG. 25, the electromechanical coupling coefficient k (%) decreases as Wwire increases from 0 μm, and the electromechanical coupling coefficient k (%) is minimized in the vicinity of Wwire=10 μm. The electromechanical coupling coefficient k (%) is improved as the Wwire increases from 10 μm, and the electromechanical coupling coefficient k (%) is maximized in the vicinity of Wwire=40 μm. It is considered that the reason why the electromechanical coupling coefficient k (%) increases with an increase in Wwire in a range of 10 μm<Wwire<40 μm is that the first extended electrode 15a having a wide width behaves as a part of the first excitation electrode 14a.

From the viewpoint of suppressing the vibration leakage, it is desirable that the Wwire is small, but as the Wwire is small, as shown in FIG. 25, the electromechanical coupling coefficient k (%) is decreased. Therefore, in order to suppress the decrease in the electromechanical coupling coefficient k (%) and the Q value, it is necessary to reduce the Wwire and then suppress the influence of the first extended electrode 15a on the second excitation electrode 14b. The third exemplary embodiment and the fourth exemplary embodiment are exemplary aspects of the present disclosure made in view of such circumstances.

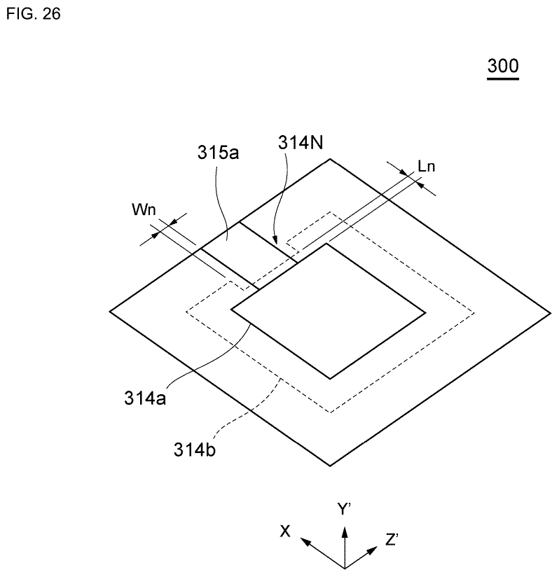

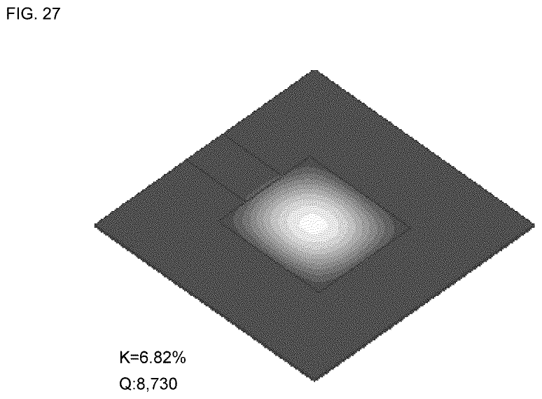

FIG. 26 is a perspective view of a vibration unit according to the third exemplary embodiment. FIG. 27 is a diagram showing a vibration distribution of the vibration unit according to the third exemplary embodiment. The size of the amplitude is indicated by light and dark, the bright portion is a region having a large amplitude and the dark portion is a region having a small amplitude. In FIG. 27, the second excitation electrode 314b is not shown.

As shown in FIG. 26, the third exemplary embodiment is different from the first exemplary embodiment in that a notch portion 314N is formed in a region of the second excitation electrode 314b facing the first extended electrode 315a, and is the same as the first exemplary embodiment in other points. Since the first extended electrode 315a extends from the outer edge portion of the first excitation electrode 314a on the X-axis positive direction side in the X-axis positive direction, the notch portion 314N is provided in the outer edge portion of the second excitation electrode 314b on the X-axis positive direction side. In plan view, the notch portion 314N is a rectangular concave portion. A distance between the outer edge portion of the second excitation electrode 314b in the notch portion 314N and the first excitation electrode 314a along the X-axis direction is defined as Ln, and a distance between the outer edge portion of the second excitation electrode 314b in the notch portion 314N and the first extended electrode 315a along the Z′-axis direction is defined as Wn.

As shown in FIG. 27, in the third exemplary embodiment, the vibrating region is limited to the region overlapping the first excitation electrode 314a, and the vibration in the region overlapping the first extended electrode 315a is suppressed. For example, when simulating in a configuration in which the first extended electrode 315a and the notch portion 314N are omitted from the third exemplary embodiment, k=6.86% and Q=8,720, but when simulating in a configuration in which the first extended electrode 315a having Wwire=10 μm is added to the configuration, k=6.77% and Q=8,540. However, when simulating in a configuration according to the third exemplary embodiment in which the notch portion 314N is further formed, k=6.82% and Q=8,730. That is, by forming the notch portion 314N, the influence of the first extended electrode 315a on the second excitation electrode 314b is suppressed, and the decrease in the electromechanical coupling coefficient k (%) and the Q value is suppressed.

As described above, according to the present exemplary embodiment, the notch portion 314N is formed in the region of the second excitation electrode 314b facing the first extended electrode 315a.

Accordingly, the influence of the first extended electrode 315a on the second excitation electrode 314b is suppressed, and the decrease in the electromechanical coupling coefficient k (%) and the Q value is suppressed.

It is noted that the third exemplary embodiment has a configuration in which the notch portion is formed in the region of the excitation electrode having the larger area of the pair of excitation electrodes in the first exemplary embodiment facing the extended electrode, but the notch portion may be formed in a region of the insulating film in the second exemplary embodiment facing the extended electrode. Even with such a configuration, the same effects as those of the third exemplary embodiment can be obtained. However, since the insulating film is lighter than the material of the excitation electrode, the vibration confinement property in a region in which the first excitation electrode and the second excitation electrode in the second exemplary embodiment face each other is good. Therefore, the decrease in the electromechanical coupling coefficient k (%) and the Q value due to the influence of the extended electrode in the second exemplary embodiment is not as large as the decrease in the electromechanical coupling coefficient k (%) and the Q value due to the influence of the extended electrode in the first exemplary embodiment. Therefore, even if the notch portion is formed in the insulating film of the second exemplary embodiment, the effect is not necessarily obtained as much as in a case in which the notch portion is formed in the first exemplary embodiment.

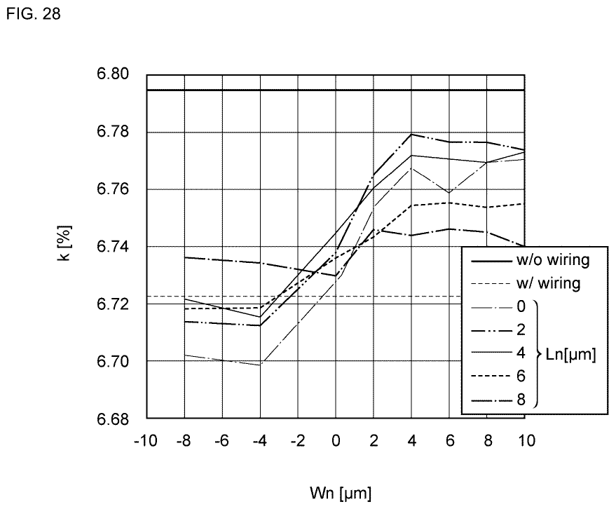

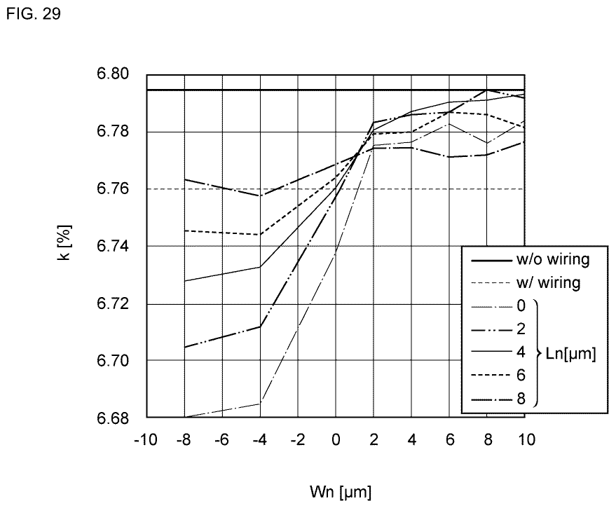

Next, FIGS. 28 and 29 are graphs showing simulation results based on the third exemplary embodiment with reference to FIGS. 28 and 29. In the graphs of FIGS. 28 and 29, the horizontal axis represents Wn(μm), and the vertical axis represents the electromechanical coupling coefficient k (%).

In FIGS. 28 and 29, the simulation conditions are as follows. FIG. 28 shows a simulation result when Wwire=10 μm, and FIG. 29 shows a simulation result when Wwire=20 μm.

$$T q = 1. µm$$

$$Te = 0.05 µm$$

$$Te 2 = 0.05 µm$$

$$Lq = W q = 120 µm$$

$$Le = 55 µm$$

$$We = 50 µm$$

$$Le 2 = 70 µm$$

$$We 2 = 60 µm$$

$$dLe = Le 2 - Le = 2 \times dLe 1 = 2 \times dLe 2 = 15 µm$$

$$dWe = We 2 - We = 2 \times dWe 1 = 2 \times dWe 2 = 10 µm$$

$$L n : variable$$

$$Wn : variable$$

As shown in FIGS. 28 and 29, it is desirable that Ln and Wn are 2 μm or more and 6 μm or less. Accordingly, the decrease in the electromechanical coupling coefficient k (%) can be suppressed regardless of the size of the Wwire.

### Fourth Exemplary Embodiment

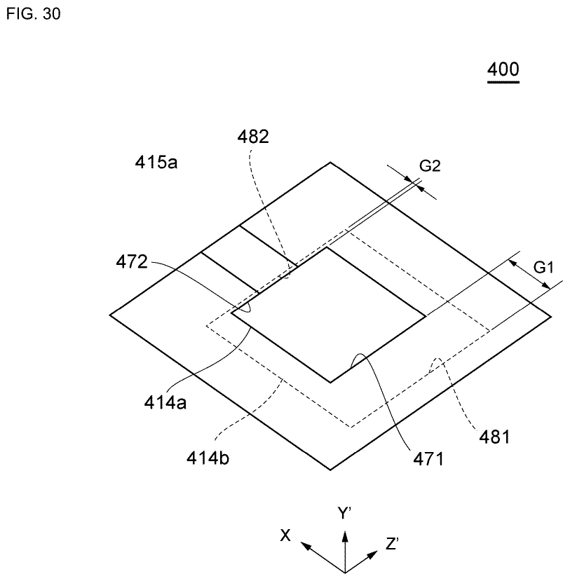

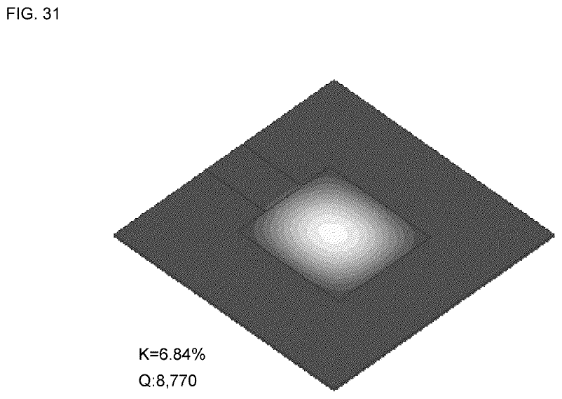

Next, a configuration of a crystal vibration element 400 according to a fourth exemplary embodiment will be described with reference to FIGS. 30 and 31. FIG. 30 is a perspective view of the vibration unit according to the fourth exemplary embodiment. FIG. 31 is a diagram showing a vibration distribution of the vibration unit according to the fourth exemplary embodiment. The size of the amplitude is indicated by light and dark, the bright portion is a region having a large amplitude and the dark portion is a region having a small amplitude. In FIG. 31, a second excitation electrode 414b is not shown.

As shown in FIG. 30, the fourth exemplary embodiment is different from the first exemplary embodiment in that, in plan view, the center of the second excitation electrode 414b is located on the X-axis negative direction side with respect to the center of the first excitation electrode 414a, and is the same as the first exemplary embodiment in other points. Since the first extended electrode 315a extends from the outer edge portion of the first excitation electrode 314a on the X-axis positive direction side in the X-axis positive direction, the center of the second excitation electrode 414b is located in a direction away from the first extended electrode 415a with respect to the center of the first excitation electrode 414a. That is, in plan view, the center of the excitation electrode having the larger area of the pair of excitation electrodes is shifted with respect to the center of the excitation electrode having the smaller area of the pair of excitation electrodes in a direction away from the extended electrode, which is electrically connected to the excitation electrode having the smaller area.

An interval between an outer edge portion 471 on the X-axis negative direction side of the first excitation electrode 414a and an outer edge portion 481 on the X-axis negative direction side of the second excitation electrode 414b along the X-axis direction is defined as G1. An interval between an outer edge portion 472 on the X-axis positive direction side of the first excitation electrode 414a and the outer edge portion 481 on the X-axis positive direction side of the second excitation electrode 414b along the X-axis direction is defined as G2. In the crystal vibration element 400, the relationship of 0≤G2<G1 is established.

As shown in FIG. 31, in the fourth exemplary embodiment, the vibrating region is limited to the region overlapping the first excitation electrode 414a, and the vibration in the region overlapping the first extended electrode 415a is suppressed. For example, when simulating in a configuration in which the first extended electrode 415a is omitted and G1=G2 from the fourth exemplary embodiment, k=6.86% and Q=8,720, but when simulating in a configuration in which the first extended electrode 415a having Wwire=10 μm is added to the configuration, k=6.77% and Q=8,540. However, when simulating in a configuration according to the fourth exemplary embodiment which is further modified to G1=0 μm, k=6.84% and Q=8,770. That is, by setting 0 μm≤G1<G2, the influence of the first extended electrode 415a on the second excitation electrode 414b is suppressed, and the decrease in the electromechanical coupling coefficient k (%) and the Q value is suppressed.

As described above, according to the present exemplary embodiment, the center of the second excitation electrode 414b is shifted with respect to the center of the first excitation electrode 414a in a direction away from the first extended electrode 415a, and the relationship of 0≤G2<G1 is established.

Accordingly, the influence of the first extended electrode 415a on the second excitation electrode 414b is suppressed, and the decrease in the electromechanical coupling coefficient k (%) and the Q value is suppressed.

### Fifth Exemplary Embodiment

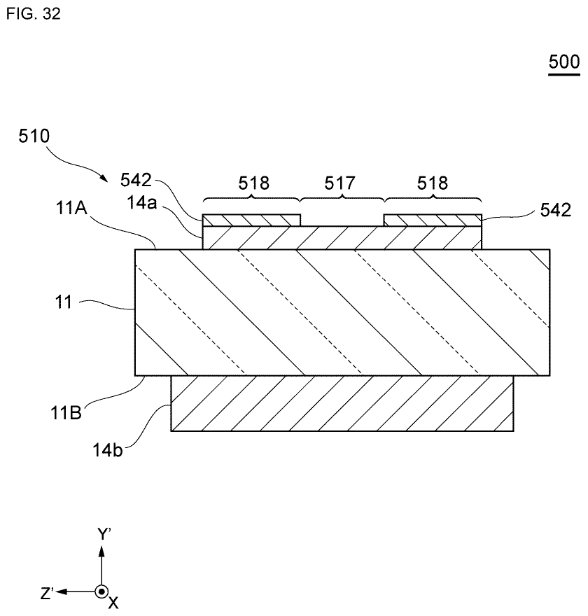

Next, a configuration of a crystal vibration element 500 according to a fifth exemplary embodiment will be described with reference to FIG. 32. FIG. 32 is a sectional view of a vibration unit according to the fifth exemplary embodiment.

The fifth exemplary embodiment is different from the first exemplary embodiment in that a mass addition film 542 is further provided, and is the same as the first exemplary embodiment in other points. The mass addition film 542 is provided on a surface of the first excitation electrode 14a on a side opposite to the crystal piece 11. In plan view, the mass addition film 542 is provided along the outer edge portion of the first excitation electrode 14a outside the center portion of the first excitation electrode 14a. In addition, in plan view, the mass addition film 542 is provided in a region that overlaps the outer edge portion of the first excitation electrode 14a or a region that is located further inward than the outer edge portion of the first excitation electrode 14a. The material of the mass addition film 542 is an electrical conductor and is the same as the material of the first excitation electrode 14a, for example.

The position and the material of the mass addition film 542 are not limited to those described above. The mass addition film 542 may be provided at any position of between the first excitation electrode 14a and the crystal piece 11, a surface of the second excitation electrode 14b on a side opposite to the crystal piece 11, or between the second excitation electrode 14b and the crystal piece 11. The material of the mass addition film 542 may be a metal different from the first excitation electrode 14a.

The mass addition film 542 reduces the acoustic velocity by a mass addition effect. Therefore, the acoustic velocity in the region in which the mass addition film 542 is provided is smaller than the acoustic velocity in the region in which the mass addition film 542 is not provided. That is, in plan view, a region in which the first excitation electrode 14a and the second excitation electrode 14b face each other has a high acoustic velocity region 517 provided in a center portion and a low acoustic velocity region 518 provided outside the high acoustic velocity region 517. The low acoustic velocity region 518 is provided, for example, in a frame shape that is continuous in the circumferential direction, but may be provided in a frame shape that is discontinuous in the circumferential direction. For example, the low acoustic velocity region 518 may be provided in a band shape extending from the outer edge portion 71 to the outer edge portion 72 or in a band shape extending from the outer edge portion 73 to the outer edge portion 74.

As a result, the electromechanical coupling coefficient k (%) of a spurious mode can be suppressed, and the electromechanical coupling coefficient k (%) of a main mode can be improved.

In the present exemplary embodiment, in a case in which the mass addition film 542 is treated as a part of the first excitation electrode 14a, the thickness Te is an average thickness of the multilayer body configured of the mass addition film 542 and the first excitation electrode 14a.

### Sixth Exemplary Embodiment

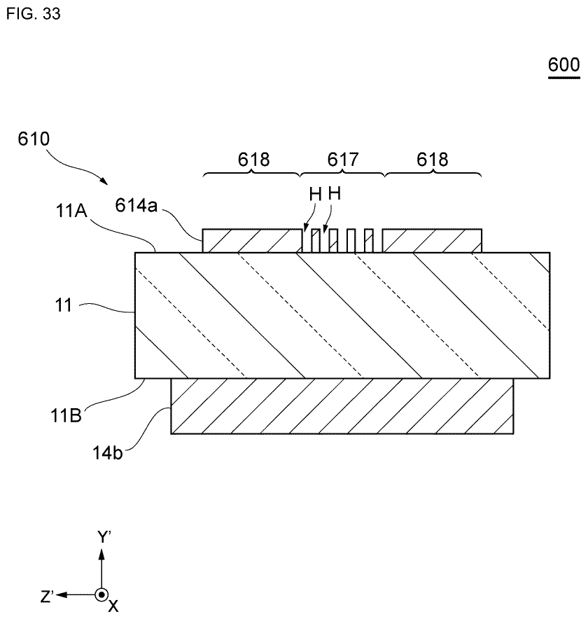

Next, a configuration of a crystal vibration element 600 according to a sixth exemplary embodiment will be described with reference to FIG. 33. FIG. 33 is a sectional view of a vibration unit according to the sixth exemplary embodiment.

The sixth exemplary embodiment is different from the first exemplary embodiment in that a plurality of hole portions H are formed at a center portion of the first excitation electrode 614a in plan view, and is the same as the first exemplary embodiment in other points.

The hole portion H penetrates the first excitation electrode 614a in the Y′-axis direction. The plurality of hole portions H increase the acoustic velocity due to the mass reduction effect. Therefore, the acoustic velocity in the region in which the plurality of hole portions H are formed is larger than the acoustic velocity in the region in which the plurality of hole portions H are not formed. That is, in plan view, a region in which the first excitation electrode 14a and the second excitation electrode 14b face each other has a high acoustic velocity region 617 provided in a center portion and a low acoustic velocity region 618 provided outside the high acoustic velocity region 617.

As a result, the electromechanical coupling coefficient k (%) of a spurious mode can be suppressed, and the electromechanical coupling coefficient k (%) of a main mode can be improved.

In the present exemplary embodiment, the area of the first excitation electrode 614a in plan view is the area of a region surrounded by the outer edge portion of the first excitation electrode 614a, and the inside of the plurality of hole portions His also calculated as a part of the area of the first excitation electrode 614a. When the thickness of the first excitation electrode 614a in the low acoustic velocity region 618 is defined as Te1 and the opening ratio of the plurality of hole portions His defined as Har, the thickness Te is calculated by the following expression.

$$Te = Te 1 \times ( 1 - Har )$$

In order to make the inside of the hole portion H in the high acoustic velocity region 617 function as a part of the first excitation electrode 614a, it is desirable that a relationship of 0<Hr/Tq≤2.0 is established when an inner diameter of the hole portion H is defined as Hr. In this case, since the decrease rate of the electrostatic capacity due to the hole portion His suppressed to 1% or less, the inside of the hole portion H can also sufficiently function as the excitation electrode. In addition, it is further desirable that the relationship of 0<Hr/Tq≤1.5 is established, and it is still further desirable that the relationship of 0<Hr/Tq≤1.0 is established. When 0<Hr/Tq≤1.5, the decrease rate of the electrostatic capacity can be suppressed to 0.5% or less, and when 0<Hr/Tq≤1.0, the decrease rate of the electrostatic capacity can be suppressed to 0.1% or less. In order to form the hole portion H with a sufficient processing accuracy, it is desirable that 0.1≤Hr/Tq, and it is further desirable that 0.5≤Hr/Tq.

The hole portion H may be formed in the second excitation electrode or may be formed in both the first excitation electrode and the second excitation electrode.

### Seventh Exemplary Embodiment

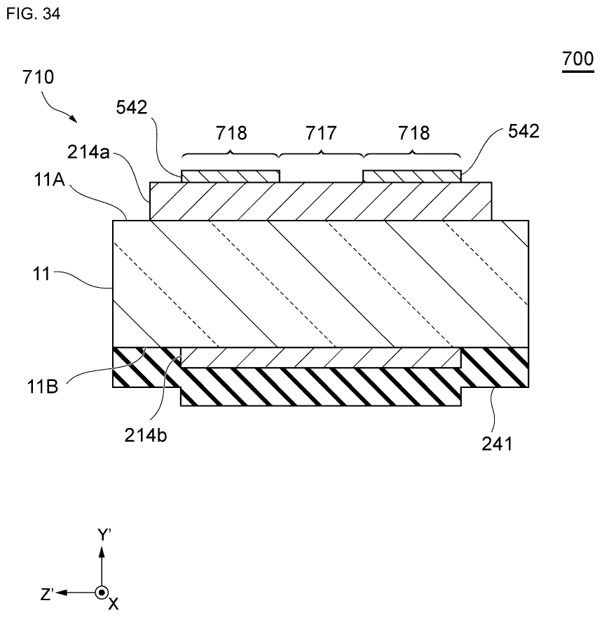

Next, a configuration of a crystal vibration element 700 according to a seventh exemplary embodiment will be described with reference to FIG. 34. FIG. 34 is a sectional view of a vibration unit according to the seventh exemplary embodiment.

The seventh exemplary embodiment is different from the second exemplary embodiment in that the mass addition film 542 is further provided and is the same as the second exemplary embodiment in other points. That is, in plan view, a region in which the first excitation electrode 214a and the second excitation electrode 214b face each other has a high acoustic velocity region 717 provided in a center portion and a low acoustic velocity region 718 provided outside the high acoustic velocity region 717. The mass addition film 542 is provided to extend from a region overlapping the outer edge portion of the second excitation electrode 214b to an inner side portion thereof. Therefore, in plan view, the low acoustic velocity region 718 is located further inward than the outer edge portion of the first excitation electrode 214a.

As a result, the electromechanical coupling coefficient k (%) of a spurious mode can be suppressed, and the electromechanical coupling coefficient k (%) of a main mode can be improved.

### Eighth Exemplary Embodiment

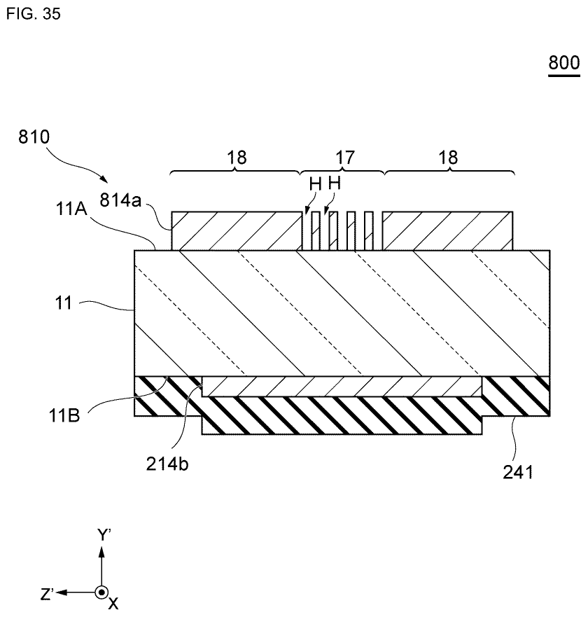

Next, a configuration of the crystal vibration element 800 according to an eighth exemplary embodiment will be described with reference to FIG. 35. FIG. 35 is a sectional view of a vibration unit according to the eighth exemplary embodiment.

The eighth exemplary embodiment is different from the second exemplary embodiment in that a plurality of hole portions H are formed at the center portion of the first excitation electrode 814a in plan view, and is the same as the second exemplary embodiment in other points.

As a result, the electromechanical coupling coefficient k (%) of a spurious mode can be suppressed, and the electromechanical coupling coefficient k (%) of a main mode can be improved.

Hereinafter, a part or all of the exemplary embodiments of the present disclosure will be appended below. The present disclosure is not limited to the following addendum.
<1>A piezoelectric vibration element is provided that includes a piezoelectric piece having a first main surface and a second main surface facing the first main surface; a first excitation electrode provided on the first main surface; and a second excitation electrode provided on the second main surface, in which in plan view in a facing direction in which the first main surface and the second main surface face each other, an area of the second excitation electrode is larger than an area of the first excitation electrode, and a part of the second excitation electrode overlaps an entirety of the first excitation electrode, and a thickness of the second excitation electrode along the facing direction is larger than a thickness of the first excitation electrode along the facing direction.

The piezoelectric vibration element according to <1>, in which in plan view in the facing direction, an entirety of an outer edge portion of the first excitation electrode is located further inward than an outer edge portion of the second excitation electrode.

> The piezoelectric vibration element according to <1> or <2>, in which when the thickness of the first excitation electrode along the facing direction is defined as Te (μm), the thickness of the second excitation electrode along the facing direction is defined as Te2 (μm), and a thickness of the piezoelectric piece along the facing direction is defined as Tq (μm), and when an average density of the first excitation electrode and the second excitation electrode is defined as ρ(kg/m³), a relationship of Te2/Tq=0.00001×ρ+0.39×Te/Tq+0.16+0.01 is established.
<4>A piezoelectric vibration element including: a piezoelectric piece having a first main surface and a second main surface facing the first main surface; a first excitation electrode provided on the first main surface; a second excitation electrode provided on the second main surface; and an insulating film stacked on the second excitation electrode, in which in plan view in a facing direction in which the first main surface and the second main surface face each other, an area of a multilayer body configured of the second excitation electrode and an insulating film is larger than an area of the first excitation electrode, and a part of the multilayer body overlaps an entirety of the first excitation electrode, and a sum of a thickness of the second excitation electrode along the facing direction and a thickness of the insulating film along the facing direction is larger than a thickness of the first excitation electrode along the facing direction.
<5> The piezoelectric vibration element according to <4>, in which the insulating film is stacked on a surface of the second excitation electrode on a side opposite to the piezoelectric piece.

The piezoelectric vibration element according to <4> or <5>, in which in plan view in the facing direction, an entirety of an outer edge portion of the second excitation electrode is provided further inward than an outer edge portion of the first excitation electrode, and an entirety of an outer edge portion of the insulating film is provided further outward than the outer edge portion of the first excitation electrode.
<7> The piezoelectric vibration element according to any one of <4> to <6>, in which the thickness of the second excitation electrode along the facing direction is smaller than the thickness of the first excitation electrode along the facing direction.

The piezoelectric vibration element according to any one of <4> to <7>, in which when the thickness of the first excitation electrode along the facing direction is defined as Te (μm), the thickness of the second excitation electrode along the facing direction is defined as Te2 (μm), a thickness of the insulating film along the facing direction is defined as Te3 (μm), and a thickness of the piezoelectric piece along the facing direction is defined as Tq (μm), and when an average density of the first excitation electrode, the second excitation electrode, and the insulating film is defined as p′ (kg/m³), a relationship of (Te2+Te3)/Tq=0.00001×p′+0.39×Te/Tq+0.16+0.01 is established.

> The piezoelectric vibration element according to <8>, in which materials of the first excitation electrode and the second excitation electrode are aluminum, and a material of the insulating film is silicon oxide.
<10> The piezoelectric vibration element according to any one of <1> to <9>, further including: a first extended electrode provided on the first main surface and electrically connected to the first excitation electrode; and a second extended electrode provided on the second main surface and electrically connected to the second excitation electrode, in which in an excitation electrode, of the first excitation electrode and the second excitation electrode, having a larger area in plan view in the facing direction, a notch portion is formed in a region facing an extended electrode, of the first extended electrode and the second extended electrode, electrically connected to an excitation electrode, of the first excitation electrode and the second excitation electrode, having a smaller area in plan view in the facing direction.
<11> The piezoelectric vibration element according to any one of <1> to <10>, further including: a first extended electrode provided on the first main surface and electrically connected to the first excitation electrode; and a second extended electrode provided on the second main surface and electrically connected to the second excitation electrode, in which a center of an excitation electrode, of the first excitation electrode and the second excitation electrode having a larger area in plan view in the facing direction is shifted with respect to a center of an excitation electrode, of the first excitation electrode and the second excitation electrode, having a smaller area in plan view in the facing direction in a direction away from an extended electrode, of the first extended electrode and the second extended electrode, electrically connected to the excitation electrode having the smaller area.
<12> The piezoelectric vibration element according to any one of <1> to <11>, in which in plan view in the facing direction, a region in which the first excitation electrode and the second excitation electrode face each other includes a high acoustic velocity region provided in a center portion and a low acoustic velocity region provided outside the high acoustic velocity region.
<13> The piezoelectric vibration element according to any one of <1> to <12>, in which in plan view in the facing direction, the first excitation electrode and the second excitation electrode have rectangular shapes, are provided with centers coinciding with each other, and have sides parallel to each other extending in a first direction and sides parallel to each other extending in a second direction intersecting the first direction, and when, in plan view in the facing direction, a distance between sides, of the first excitation electrode and the second excitation electrode, adjacent to each other in a direction is defined as De (μm), and when a thickness of the piezoelectric piece along the facing direction is defined as Tq (μm), a relationship of 5.22×Tq−0.45≤De is established.
<14> The piezoelectric vibration element according to any one of <1> to <13>, in which a main vibration mode is thickness shear vibration.
<15> The piezoelectric vibration element according to any one of <1> to <14>, in which the piezoelectric piece is a crystal piece.
<16> The piezoelectric vibration element according to <15>, in which a cut-angle of the crystal piece is an AT cut, a BT cut, or an ST cut.

In the present specification, the crystal vibration element (quartz crystal resonator) including the crystal piece (quartz crystal element) as the piezoelectric piece (piezoelectric element) is described as an example, but the piezoelectric vibration element (piezoelectric resonator) is not limited thereto. As a piezoelectric piece that is used for the piezoelectric vibrator according to the present exemplary embodiment, for example, a piezoelectric ceramic such as lead zirconate titanate (PZT) or aluminum nitride, a piezoelectric single crystal such as lithium niobate or lithium tantalate can be used, but it is not limited thereto, and can be selected as appropriate.

The exemplary embodiments according to the present disclosure are not particularly limited, and can be appropriately applied to any device that performs electromechanical energy conversion by the piezoelectric effect, such as a timing device, a sound generator, an oscillator, or a load sensor.

As described above, according to an exemplary aspect of the present disclosure, a piezoelectric vibration element of improved electromechanical coupling coefficient is provided.

The exemplary embodiments described above are for facilitating the understanding of the present disclosure, and are not intended to be construed as limiting the present disclosure. The present disclosure may be changed/improved without departing from the concept of the present disclosure, and the present disclosure also includes equivalents thereof. That is, the scope of the present disclosure includes designs obtained by appropriately changing the exemplary embodiments and/or the modification examples by those skilled in the art as long as the designs have the characteristics of the present disclosure. For example, each component included in the exemplary embodiments and/or the modification examples, arrangement, a material, a condition, a shape, a size, and the like of the component are not limited to those illustrated, and can be changed as appropriate. In addition, the exemplary embodiments and the modification examples are merely examples, and it goes without saying that partial substitutions or combinations of the configurations illustrated in the different exemplary embodiments and/or modification examples can be made, and substitutions or combinations are also included within the scope of the present disclosure as long as the substitutions or combinations include the characteristics of the present disclosure.

### REFERENCE SIGNS LIST

1 crystal vibrator
10 crystal vibration element
11 crystal piece
11A upper surface
11B lower surface
14a first excitation electrode
14b second excitation electrode
15a first extended electrode
15b second extended electrode
16a first connection electrode
16b second connection electrode
Lq length of crystal piece along X-axis direction
Wq length of crystal piece along Z′-axis direction
Tq thickness of crystal piece
Le length of first excitation electrode along X-axis direction
We length of first excitation electrode along Z′-axis direction
Te thickness of first excitation electrode
Le2 length of second excitation electrode along X-axis direction
We2 length of second excitation electrode along Z′-axis direction
Te2 thickness of second excitation electrode

What is claimed is:

1. A piezoelectric vibration element, comprising:
a piezoelectric piece having a first main surface and a second main surface that face each other in a facing direction;
a first excitation electrode on the first main surface; and
a second excitation electrode on the second main surface,
wherein:
in a plan view in the facing direction, a first area of the first excitation electrode is smaller than a second area of the second excitation electrode, and a part of the second excitation electrode overlaps an entirety of the first excitation electrode, and
a first thickness of the first excitation electrode along the facing direction is smaller than a second thickness of the second excitation electrode along the facing direction.

2. The piezoelectric vibration element according to claim 1, wherein, in the plan view in the facing direction, an entirety of a first outer edge portion of the first excitation electrode is farther inward than a second outer edge portion of the second excitation electrode.

3. The piezoelectric vibration element according to claim 1, wherein:
the first thickness of the first excitation electrode along the facing direction is denoted as Te (in μm), the second thickness of the second excitation electrode along the facing direction is denoted as Te2 (in μm), a third thickness of the piezoelectric piece along the facing direction is denoted as Tq (in μm), and an average density of the first excitation electrode and the second excitation electrode denoted as ρ(in kg/m³), have a relationship of:
$$Te 2 / Tq = 0.00 \; 001 \times ρ + 0.39 \times Te / Tq + 0.16 \pm 0.01 .$$

4. The piezoelectric vibration element according to claim 1, further comprising:
a first extended electrode on the first main surface that is electrically connected to the first excitation electrode; and
a second extended electrode on the second main surface that is electrically connected to the second excitation electrode,
wherein the second excitation electrode has a notch portion in a region facing the first extended electrode.

5. The piezoelectric vibration element according to claim 1, further comprising:
a first extended electrode on the first main surface that is electrically connected to the first excitation electrode; and
a second extended electrode on the second main surface that is electrically connected to the second excitation electrode,
wherein a second center of a second excitation electrode is shifted with respect to a first center of the first excitation electrode in a direction away from the first extended electrode.

6. The piezoelectric vibration element according to claim 1, wherein, in the plan view in the facing direction, an overlapping region of the first excitation electrode and the second excitation electrode includes a high acoustic velocity region in a center portion of the overlapping region and a low acoustic velocity region outside the high acoustic velocity region.

7. The piezoelectric vibration element according to claim 1, wherein:
in the plan view in the facing direction, the first excitation electrode has a first rectangular shape with first sides and the second excitation electrode has a second rectangular shape with second sides,
the first rectangular shape and the second rectangular shape have centers coinciding with each other,
the first sides of the first rectangular shape are respectively parallel to the second sides of the second rectangular shape, and
a distance between the first sides and the second sides denoted as De (in μm), and a thickness of the piezoelectric piece along the facing direction denoted as Tq (in μm) have a relationship of 5.22×Tq−0.45≤De.

8. The piezoelectric vibration element according to claim 1, wherein a main vibration mode of the piezoelectric vibration element is thickness shear vibration.

9. The piezoelectric vibration element according to claim 1, wherein the piezoelectric piece is a crystal piece.

10. The piezoelectric vibration element according to claim 9, wherein a cut-angle of the crystal piece is an AT cut, a BT cut, or an ST cut.

11. A piezoelectric vibration element, comprising:
a piezoelectric piece having a first main surface and a second main surface, the first main surface and the second main surface facing each other in a facing direction;
a first excitation electrode on the first main surface;
a second excitation electrode on the second main surface; and
an insulating film stacked on the second excitation electrode, the insulating film and the second excitation electrode being configured to form a multilayer body,
wherein:
in a plan view in the facing direction, a first area of the first excitation electrode is smaller than a second area of the multilayer body, and a part of the multilayer body overlaps an entirety of the first excitation electrode, and
a first thickness of the first excitation electrode along the facing direction is smaller than a sum of a second thickness of the second excitation electrode along the facing direction and a third thickness of the insulating film along the facing direction.

12. The piezoelectric vibration element according to claim 11, wherein the insulating film is stacked on the second excitation electrode on an opposite side to the piezoelectric piece.

13. The piezoelectric vibration element according to claim 11, wherein:
in the plan view in the facing direction, an entirety of a second outer edge portion of the second excitation electrode is further inward than a first outer edge portion of the first excitation electrode, and
an entirety of a third outer edge portion of the insulating film is farther outward than the first outer edge portion of the first excitation electrode.

14. The piezoelectric vibration element according to claim 11, wherein the second thickness of the second excitation electrode along the facing direction is smaller than the first thickness of the first excitation electrode along the facing direction.

15. The piezoelectric vibration element according to claim 11, wherein:
the first thickness of the first excitation electrode along the facing direction is denoted as Te (in μm), the second thickness of the second excitation electrode along the facing direction is denoted as Te2 (in μm), the third thickness of the insulating film along the facing direction is denoted as Te3 (in μm), a fourth thickness of the piezoelectric piece along the facing direction is denoted as Tq (μm), and an average density of the first excitation electrode, the second excitation electrode, and the insulating film denoted as p′ (kg/m³) have a relationship of:
$$( Te 2 + Te 3 ) / Tq = 0.00 \; 001 \times {ρ}^{′} + 0.39 \times Te / Tq + 0.16 \pm 0.01 .$$

16. The piezoelectric vibration element according to claim 15, wherein:
the first excitation electrode and the second excitation electrode are each aluminum, and
the insulating film includes silicon oxide.

17. The piezoelectric vibration element according to claim 11, further comprising:
a first extended electrode on the first main surface that is electrically connected to the first excitation electrode; and
a second extended electrode on the second main surface that is electrically connected to the second excitation electrode,
wherein the second excitation electrode has a notch portion in a region facing the first extended electrode.

18. The piezoelectric vibration element according to claim 11, further comprising:
a first extended electrode on the first main surface that is electrically connected to the first excitation electrode; and
a second extended electrode on the second main surface that is electrically connected to the second excitation electrode,
wherein a first center of the first excitation electrode is shifted with respect to a second center of the second excitation electrode in a direction away from the second extended electrode.

19. The piezoelectric vibration element according to claim 11, wherein, in the plan view in the facing direction, an overlapping region of the first excitation electrode and the second excitation electrode includes a high acoustic velocity region in a center portion of the overlapping region and a low acoustic velocity region outside the high acoustic velocity region.

20. The piezoelectric vibration element according to claim 11, wherein:
in the plan view in the facing direction, the first excitation electrode has a first rectangular shape with first sides and the second excitation electrode has a second rectangular shape with second sides,
the first rectangular shape and the second rectangular shape have centers coinciding with each other,
the first sides of the first rectangular shape are respectively parallel to the second sides of the second rectangular shape, and
a distance between the first sides and the second sides denoted as De (in μm), and a thickness of the piezoelectric piece along the facing direction denoted as Tq (in μm) have a relationship of 5.22×Tq−0.45≤De.
